(19) United States
(12) Patent Application Publication
(10) Pub. No.: US 2025/0228023 A1
(43) Pub. Date: Jul. 10, 2025

(54) IMAGE SENSOR AND ELECTRONIC APPARATUS INCLUDING THE IMAGE SENSOR

(71) Applicant: SAMSUNG ELECTRONICS CO., LTD., Suwon-si (KR)

(72) Inventors: Junho LEE, Suwon-si (KR); Sookyoung ROH, Suwon-si (KR); Hyunsung PARK, Suwon-si (KR)

(73) Assignee: SAMSUNG ELECTRONICS CO., LTD., Suwon-si (KR)

(21) Appl. No.: 18/894,481

(22) Filed: Sep. 24, 2024

(30) Foreign Application Priority Data
Jan. 3, 2024 (KR) 10-2024-0000903

(51) Int. Cl. H01L 27/146; H01L 31/105

(52) U.S. Cl. CPC H10F 39/8027; H10F 30/223; H10F 39/182; H10F 39/8037; H10F 39/809

(57) ABSTRACT

Provided is an image sensor including a pixel array including pixels disposed two dimensionally, and a circuit board including transistors respectively corresponding to the pixels, each of the pixels includes a first meta photodiode configured to absorb light in a first wavelength band, a second meta photodiode configured to absorb light in a second wavelength band different from the first wavelength band, and a third meta photodiode configured to absorb light in a third wavelength band different from the first wavelength band and the second wavelength band, and each of the first meta photodiode, the second meta photodiode, and the third meta photodiode includes a rod layer extending in a first direction and having a first width in a second direction perpendicular to the first direction, and a base layer between the rod layer and the circuit board, the base layer having a second width greater than the first width.

### CROSS-REFERENCE TO RELATED APPLICATION

This application claims priority to Korean Patent Application No. 10-2024-0000903, filed on Jan. 3, 2024, in the Korean Intellectual Property Office, the disclosure of which is incorporated by reference herein in its entirety.

### BACKGROUND

### 1. Field

Example embodiments of the present disclosure relate to an image sensor and an electronic apparatus including the image sensor.

### 2. Description of Related Art

An image sensor may sense a color of incident light by using a color filter. However, because the color filter absorbs light of a color other than the light of the corresponding color, the light utilization efficiency of the image sensor may be reduced. For example, when a red-green-blue (RGB) color filter is used, because only ⅓ of incident light is transmitted and the remaining ⅔ is absorbed, the light utilization efficiency of the image sensor is only about 33%. Most light loss of an image sensor is caused by a color filter. Accordingly, a method of separating a color into each pixel PX of an image sensor without using a color filter has been attempted.

On the other hand, as the demand for high resolution image sensors increases, pixel sizes have been gradually decreased, which may limit the color separation function. In addition, in the color separation method, because energy entering a unit pixel is divided and absorbed into R, G, and B effective areas, each sub-pixel is responsible for one color, and resolution degradation may occur due to under-sampling, which is basically present in signal processing. Accordingly, a method of implementing full color pixels suitable for high resolution implementation is needed.

### SUMMARY

One or more example embodiments provide an image sensor having a full color pixel and an electronic apparatus including the image sensor.

Additional aspects will be set forth in part in the description which follows and, in part, will be apparent from the description, or may be learned by practice of the example embodiments.

According to an aspect of an example embodiment, there is provided an image sensor including a pixel array including a plurality of pixels disposed in a two-dimensional (2D) arrangement, and a circuit board including a plurality of transistors respectively corresponding to the plurality of pixels, wherein each pixel of the plurality of pixels includes a first meta photodiode configured to absorb light in a first wavelength band, a second meta photodiode configured to absorb light in a second wavelength band different from the first wavelength band, and a third meta photodiode configured to absorb light in a third wavelength band different from the first wavelength band and the second wavelength band, and wherein each of the first meta photodiode, the second meta photodiode, and the third meta photodiode includes a rod layer extending in a first direction and having a first width in a second direction perpendicular to the first direction, and a base layer between the rod layer and the circuit board, the base layer having a second width, in the second direction, greater than the first width.

A size of the first width of the rod layer included in the first meta photodiode, a size of the first width of the rod layer included in the second meta photodiode, and a size of the first width of the rod layer included in the third meta photodiode may be different from each other.

The second width of the base layer included in the first meta photodiode, the second width of the base layer included in the second meta photodiode, and the second width of the base layer included in the third meta photodiode may be the same.

A smallest width among the second width of the base layer included in the first meta photodiode, the second width of the base layer included in the second meta photodiode, and the second width of the base layer included in the third meta photodiode may be greater than a largest width among the first width of the rod layer included in the first meta photodiode, the first width of the rod layer included in the second meta photodiode, and the first width of the rod layer included in the third meta photodiode.

A cross-sectional shape of the rod layer is different from a cross-sectional shape of the base layer.

Gaps between the base layer included in the first meta photodiode, the base layer included in the second meta photodiode, and the base layer included in the third meta photodiode may be same as each other.

Gaps between the base layer included in the first meta photodiode, the base layer included in the second meta photodiode, and the base layer included in the third meta photodiode may be less than or equal to 30 nm.

Gaps between the base layer included in the first meta photodiode, the base layer included in the second meta photodiode, and the base layer included in the third meta photodiode may be different from each other.

The rod layer may entirely overlap the base layer in the first direction.

The rod layer may include an intrinsic semiconductor material.

The base layer may include a p-type semiconductor region and an n-type semiconductor region.

The rod layer may include a p-type semiconductor material.

The rod layer may be in contact with the p-type semiconductor region included in the base layer.

A ratio of a length of the rod layer to a length of the base layer may be greater than or equal to 0.5 and less than or equal to 1.5.

A length of the rod layer may be greater than or equal to 0.5 μm and less than or equal to 3 μm.

A length of the base layer may be greater than or equal to 1 μm and less than or equal to 3 μm.

The second width of the base layer may be greater than or equal to a width of a gate electrode of a transistor that is included in the circuit board and contacts the base layer.

A gap between a central axis of the rod layer and a central axis of each pixel of the plurality of pixels may be less than or equal to a gap between a central axis of the base layer and the central axis of each pixel of the plurality of pixels.

A width of each pixel of the plurality of pixels may satisfy p≤D, where D denotes a diffraction limit and p denotes a width of each pixel in a direction defining the two-dimensional (2D) arrangement of the plurality of pixels.

The image sensor may further include a first insulating layer between the rod layer included in the first meta photodiode, the rod layer included in the second meta photodiode, and the rod layer included in the third meta photodiode, and a second insulating layer between the base layer included in the first meta photodiode, the base layer included in the second meta photodiode, and the base layer included in the third meta photodiode, wherein a refractive index of the second insulating layer being less than a refractive index of the first insulating layer.

According to another aspect of an example embodiment, there is provided an image sensor including a pixel array including a plurality of pixels, and a circuit board including a plurality of transistors respectively corresponding to the plurality of pixels, wherein each pixel of the plurality of pixels including a first meta photodiode configured to absorb light in a first wavelength band, the first meta photodiode including a first rod layer and a first base layer, a second meta photodiode configured to absorb light in a second wavelength band different from the first wavelength band, the second meta photodiode including a second rod layer and a second base layer, and a third meta photodiode configured to absorb light in a third wavelength band different from the first wavelength band and the second wavelength band, the third meta photodiode including a third rod layer and a third base layer, wherein a cross-sectional area of the first base layer is greater than a cross-sectional area of the first rod layer, a cross-sectional area of the second base layer is greater than a cross-sectional area of the second rod layer, and a cross-sectional area of the third base layer is greater than a cross-sectional area of the third rod layer, and wherein the first base layer is between the first rod layer and the circuit board, the second base layer is between the second rod layer and the circuit board, and the third base layer is between the third rod layer and the circuit board.

### BRIEF DESCRIPTION OF DRAWINGS

The above and other aspects, features, and advantages of example embodiments will be more apparent from the following description taken in conjunction with the accompanying drawings, in which:

FIG. 1 is a schematic block diagram of an image sensor according to an example embodiment;

FIG. 2 is a plan view illustrating a pixel arrangement of a pixel array of the image sensor of FIG. 1;

FIG. 3 is a detailed perspective view of one pixel included in the image sensor of FIG. 1;

FIG. 4 is a plan view of a pixel array including the pixel of FIG. 3;

FIG. 5A is a cross-sectional view taken along a line A-A of FIG. 4;

FIG. 5B is a cross-sectional view taken along a line B-B of FIG. 4;

FIG. 6A is a result illustrating an absorption spectrum according to a wavelength of a first meta photodiode according to an example embodiment;

FIG. 6B is a result illustrating an absorption spectrum according to a wavelength of a second meta photodiode according to an example embodiment;

FIG. 6C is a result illustrating an absorption spectrum according to a wavelength of a third meta photodiode according to an example embodiment;

FIG. 7A is a result illustrating an absorption spectrum according to wavelengths of a first rod layer included in the first meta photodiode for each length according to an example embodiment;

FIG. 7B is a result illustrating an absorption spectrum according to wavelengths of a second rod layer included in the second meta photodiode for each length according to an example embodiment;

FIG. 7C is a result illustrating an absorption spectrum according to wavelengths of a third rod layer included in the third meta photodiode for each length according to an example embodiment;

FIG. 8A is a result illustrating an absorption spectrum of a first meta photodiode according to a width of a first base layer according to an example embodiment;

FIG. 8B is a result illustrating an absorption spectrum of a second meta photodiode according to a width of a second base layer according to an example embodiment;

FIG. 8C is a result illustrating an absorption spectrum of a third meta photodiode according to a width of a third base layer according to an example embodiment;

FIGS. 9A and 9B are diagrams illustrating a pixel according to another example embodiment;

FIG. 10 is a diagram illustrating a pixel according to another example embodiment;

FIG. 11 is a diagram illustrating a pixel according to another example embodiment;

FIG. 12 is a perspective view illustrating a schematic structure of an image sensor according to another example embodiment;

FIGS. 13, 14, 15, and 16 are plan views illustrating arrangement forms of various types of meta photodiodes provided in one pixel in each of image sensors according to example embodiments;

FIG. 17 is a cross-sectional view illustrating a structure of a pixel array of an image sensor according to another example embodiment;

FIG. 18 is a block diagram of an electronic apparatus including an image sensor;

FIG. 19 is a block diagram illustrating a camera module included in the electronic apparatus of FIG. 18;

FIG. 20 is a block diagram of an electronic apparatus including a multi-camera module; and

FIG. 21 is a detailed block diagram of a camera module of the electronic apparatus shown in FIG. 20.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an image sensor and an electronic apparatus including the image sensor according to various embodiments will be described in detail with reference to the accompanying drawings. Like reference numerals in the drawings denote like elements, and the size of each element in the drawings may be exaggerated for clarity and convenience of description.

The singular forms are intended to include the plural forms as well, unless the context clearly indicates otherwise. Also, when a part “includes” any element, it means that the part may further include other elements, rather than excluding other elements, unless otherwise stated. Sizes or thicknesses of components in the drawings may be arbitrarily exaggerated for convenience of explanation. Further, when a certain material layer is described as being on a substrate 101 or another layer, the material layer may be in contact with the substrate 101 or the other layer, or there may be a third layer between the material layer and the substrate 101 or the other layer. Also, materials constituting each layer are provided merely as an example, and other materials may also be used.

In addition, the terms “ . . . unit”, “module”, etc. described herein mean a unit that processes at least one function or operation, may be implemented as hardware or software, or may be implemented as a combination of hardware and software.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail

Connections of lines or connection members between elements shown in the drawings are illustrative of functional connections and/or physical or circuitry connections, and may be replaced in an actual device, or may be represented as additional various functional connections, physical connections, or circuitry connections.

The term “the” and the similar indicative terms may be used in both the singular and the plural.

The expression such as “at least” used to list elements is intended to limit a list of entire elements, rather than individual elements in the list. For example, expressions such as “at least one of A, B, and C” or “at least one selected from the group consisting of A, B, and C” may be interpreted as only A, only B, only C, or a combination of two or more of A, B, and C, e.g., ABC, AB, BC, and AC

When the terms such as “about” or “substantially” are used in relation to numerical values, the relevant numerical value may be construed as including a manufacturing or operation deviation (e.g., ±10%) of the stated numerical value. In addition, when the expressions such as “generally” and “substantially” are used in relation to a geometric shape, the geometric precision may not be required, and the intention is that the degree of tolerance regarding the shape is within the scope of embodiment. Moreover, regardless of whether a numerical value of a shape is limited by using “about” or “substantially”, such a numerical value or shape should be understood as including a manufacturing or operation deviation (e.g., ±10%) of the stated numerical value

It will be understood that although the terms “first,” “second,” etc. may be used herein to describe various components, these components are not defined by the terms. These terms are only used to distinguish one component from another.

The use of all examples or example terms is merely for describing the technical concept in detail, and the scope thereof is not limited by these examples or example terms unless limited by claims.

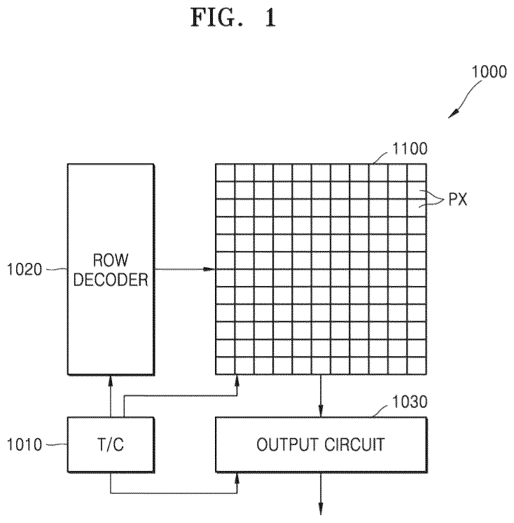

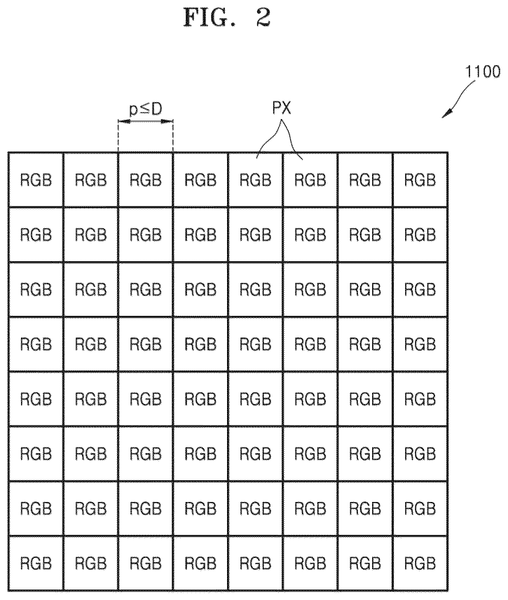

FIG. 1 is a schematic block diagram of an image sensor 1000 according to an example embodiment. FIG. 2 is a plan view illustrating a pixel PX arrangement of a pixel array 1100 of the image sensor 1000 of FIG. 1.

Referring to FIGS. 1 and 2, the image sensor 1000 may include the pixel array 1100, a timing controller 1010, a row decoder 1020, and an output circuit 1030. The pixel array 1100 includes a plurality of pixels PXs two-dimensionally disposed along a plurality of rows and columns. Each of the pixels PX may include a plurality of meta photodiodes.

The row decoder 1020 selects one row from among rows of the pixel array 1100 in response to a row address signal output from the timing controller 1010. The output circuit 1030 outputs a photo-sensing signal in column units from the plurality of pixels PX disposed along the selected row. To this end, the output circuit 1030 may include a column decoder and an analog-to-digital converter (ADC). For example, the output circuit 1030 may include a plurality of ADCs respectively disposed for columns between the column decoder and the pixel array 1100, or one ADC disposed at an output terminal of the column decoder. The timing controller 1010, the row decoder 1020, and the output circuit 1030 may be implemented as a single chip or as separate chips. A processor for processing an image signal output by the output circuit 1030 may be implemented as a single chip together with the timing controller 1010, the row decoder 1020, and the output circuit 1030.

The plurality of pixels PX constituting the pixel array 1100 may be full-color pixels PX each sensing an arbitrary color. For example, light incident on the pixel PXI may be sensed separately for each wavelength band, for example, amounts of a red light component, a green light component, and a blue light component. Accordingly, the loss of light of a specific color according to a color of a sub-pixel PX, which occurs in an image sensor having a color filter of related art, does not occur in the image sensor 1000 of the example embodiment. For example, each color component of light incident on the pixel PXI may be detected almost regardless of a position of a region within the pixel PXI. In this regard, the pixel PX of the image sensor 1000 according to the example embodiment may be referred to as a full-color pixel or an RGB pixel in a sense of distinguishing from a red pixel PX, a green pixel PX, a blue pixel PX, etc., which recognize only specific colors.

The pixels PX may be two-dimensionally disposed as shown in FIG. 2, and a width p of the pixel PX has a size equal to or less than a diffraction limit D. Here, the width p may denote a width in one direction defining a two-dimensional arrangement, and the widths p in both directions may be equal to or less than the diffraction limit D.

The diffraction limit D may be a minimum size to which an object may be imaged discriminatively, and is expressed by the following Equation 1.

D=∥/(2NA)=λ*F [Equation 1]

Here, λ denotes a wavelength of incident light, and NA and F denote a numerical aperture and F-number of an imaging optical system (or a lens assembly), respectively.

NA is defined as a sine value of an edge ray angle in an imaging space, and the larger the NA, the larger the angular distribution of focused light. F-number is defined by a relation of 1/(2NA). According to a trend towards high resolution and miniaturization of imaging systems, an edge ray angle tends to increase, and accordingly, modular lenses with a relatively small F-number are being developed. When an F-number that may be reduced is about 1.0, the diffraction limit D becomes λ.

Under this condition, the diffraction limit D with respect to a central wavelength of blue light may be expressed as, for example, about 0.4 nm. For example, each pixel PX constituting the pixel array 1100 may have a size equal to or less than 450 nm×450 nm. However, this value is an example, and a specific size may vary according to an imaging optical system provided together.

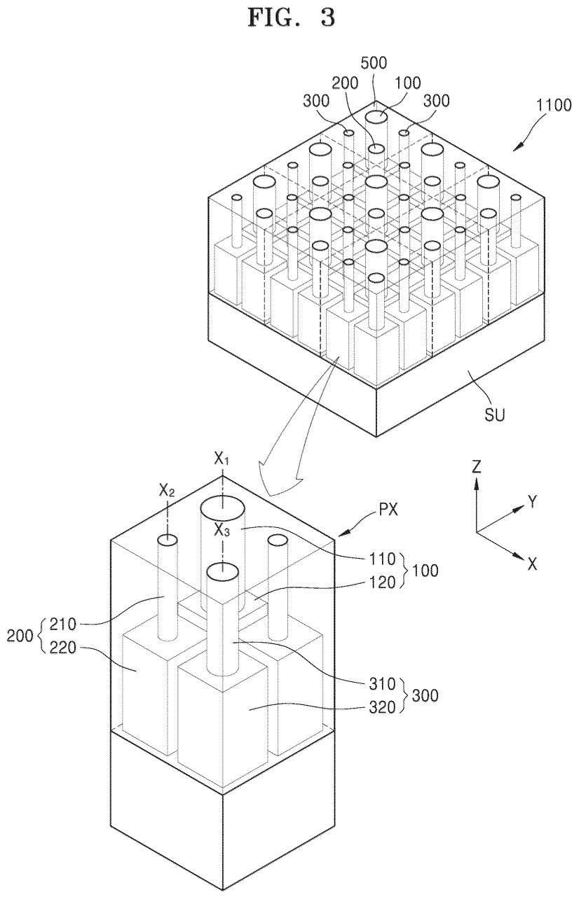

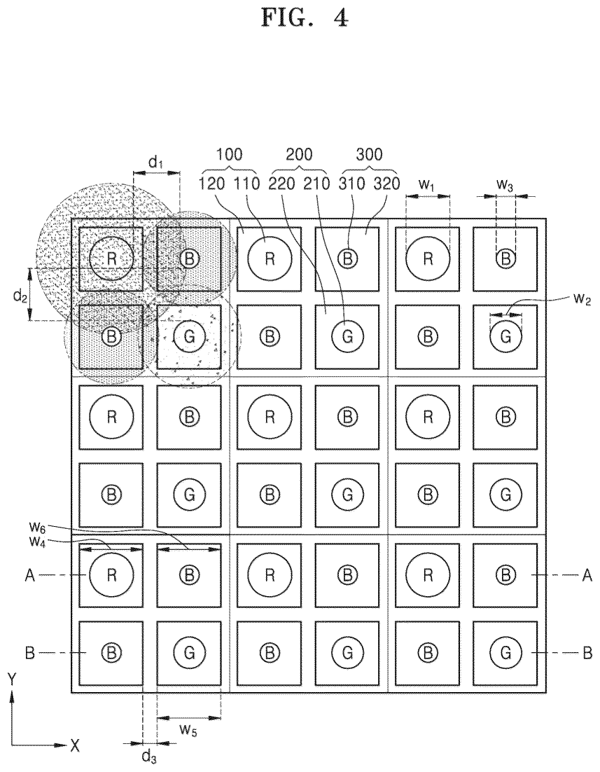

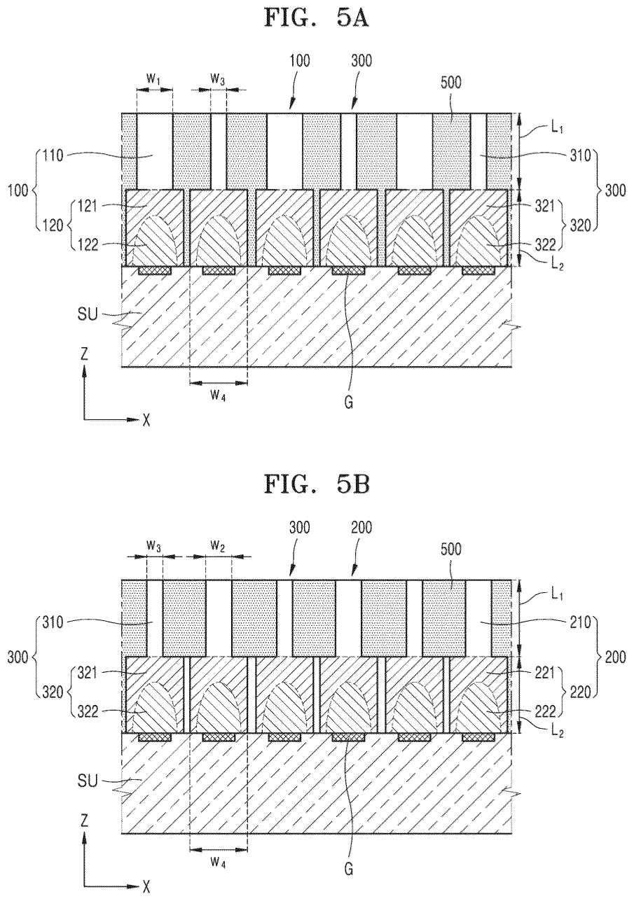

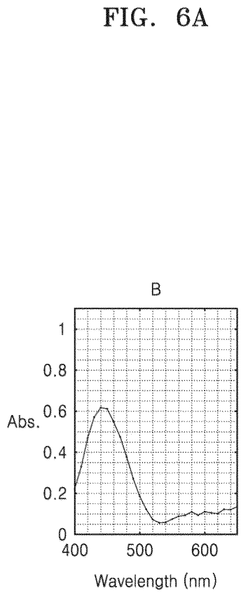

FIG. 3 is a detailed perspective view of one pixel included in the image sensor of FIG. 1. FIG. 4 is a plan view of a pixel array including the pixel of FIG. 3. FIGS. 5A and 5B are cross-sectional views taken along lines A-A and B-B of FIG. 4, respectively.

Referring to FIG. 3, each of a plurality of pixels PX included in the pixel array 1100 may include a first meta photodiode 100 selectively absorbing light in a first wavelength band (e.g., a red wavelength band), a second meta photodiode 200 selectively absorbing light in a second wavelength band (e.g., a green wavelength band) different from the first wavelength band, and a third meta photodiode 300 selectively absorbing light in a third wavelength band (e.g., a blue wavelength band) different from the first wavelength band and the second wavelength band.

The pixel array 1100 of the image sensor 1000 may further include a circuit board SU. The circuit board SU may support a plurality of first meta photodiodes 100, a plurality of second meta photodiodes 200, and a plurality of third meta photodiodes 300, and may include circuit elements that process signals in each of the pixels PX. For example, the circuit board SU may include electrodes and wiring structures for the first meta photodiode 100, the second meta photodiode 200, and the third meta photodiode 300 provided in each of the pixels PX. In addition, various circuit elements required for the image sensor 1000 may be integrally disposed on the circuit board SU. For example, the circuit board SU may further include a logic layer including various analog circuits, digital circuits, etc., and may further include a memory layer in which data is stored. The logic layer and the memory layer may be configured as different layers or the same layer. Some of the circuit elements illustrated in FIG. 1 may be provided on the circuit board SU.

Each of the first meta photodiode 100, the second meta photodiode 200, and the third meta photodiode 300 may have a shape dimension (e.g., width, height, length, diameter, etc.) smaller than a wavelength of incident light, and may selectively absorb light of a specific wavelength band through waveguide mode-based resonance.

Absorption spectra of the first meta photodiode 100, the second meta photodiode 200, and the third meta photodiode 300 may be determined according to widths, lengths l1, cross-sectional shapes, and arrangement forms of the first meta photodiode 100, the second meta photodiode 200, and the third meta photodiode 300, and a gap between two adjacent meta photodiodes among the first meta photodiode 100, the second meta photodiode 200, and the third meta photodiode 300. According to example embodiments, central axes X₁, X₂, and X₃ of the first rod layer 110, the second rod layer 210, and the third rod layer 310 may correspond to central axes X₁, X₂, and X₃ of the first base layer 120, the second base layer 220, and the third base layer 320.

In FIG. 4, dotted circles illustrated around the first meta photodiode 100, the second meta photodiode 200, and the third meta photodiode 300 conceptually show that red light, green light, and blue light are guided into the first meta photodiode 100, the second meta photodiode 200, and the third meta photodiode 300, respectively. Most of the red light incident to an arbitrary position in a pixel PX region may be absorbed by the first meta photodiode 100, most of the green light may be absorbed by the second meta photodiode 200, and most of the blue light may be absorbed by the third meta photodiode 300.

One pixel PX may include one first meta photodiode 100 that absorbs red light, one second meta photodiode 200 that absorbs green light, and two third meta photodiodes 300 that absorb blue light. For example, one first meta photodiode 100, one second meta photodiode 200, and the two third meta photodiodes 300 may be disposed so that a line connecting centers of the four meta photodiodes is a square. The first meta photodiode 100 and the second meta photodiode 200 may be disposed in a first diagonal direction of the square, and the two third meta photodiodes 300 may be disposed in a second diagonal direction crossing the first diagonal direction. However, embodiments are not limited thereto. For example, in one pixel PX, four meta photodiodes may be disposed so that a line connecting centers of the four meta photodiodes is a rectangle, or five or more meta photodiodes may be disposed.

Each of the first meta photodiode 100, the second meta photodiode 200, and the third meta photodiode 300 according to an example embodiment may include rod layers 110, 210, and 310 extending in a first direction and each having a first width in a second direction perpendicular to the first direction, and base layers 120, 220, and 320 disposed between the rod layers 110, 210, and 310 and the circuit board SU, and each having a second width greater than the first width.

Each of the rod layers 110, 210, and 310 of the first meta photodiode 100, the second meta photodiode 200, and the third meta photodiode 300 may mainly absorb light of a wavelength that satisfies each wave mode resonance requirement among incident light, and generate charges from at least part of the absorbed light. Each of the base layers 120, 220, and 320 may generate charges from the absorbed light or transfer the generated charges to the circuit board SU.

The rod layers 110, 210, and 310 and the base layers 120, 220 and 320 may be sequentially disposed in an incident direction of light. For example, lower surfaces of the rod layers 110, 210, and 310 may be respectively in contact with upper surfaces of the base layers 120, 220, and 320. In the first direction (for example, Z axis), the entire rod layers 110, 210, and 310 may respectively overlap the corresponding base layers 120, 220, and 320. Cross-sectional areas of the rod layers 110, 210, and 310 in a direction (e.g., X-axis or Y-axis) perpendicular to the first direction may be respectively smaller than cross-sectional areas of the base layers 120, 220, and 320. When the cross-sectional areas of the rod layers 110, 210, and 310 are respectively smaller than the cross-sectional areas of the base layers 120, 220, and 320, widths of the rod layers 110, 210, and 310 may be generally respectively less than widths of the base layers 120, 220, and 320. Here, the width may be the longest width, and although it is described based on the width for convenience of explanation below, the cross-sectional area may be equally applied.

Hereinafter, a rod layer of the first meta photodiode 100, a rod layer of the second meta photodiode 200, and a rod layer of the third meta photodiode 300 may be respectively referred to as the first rod layer 110, the second rod layer 210, and the third rod layer 310. In addition, a base layer of the first meta photodiode 100, a base layer of the second meta photodiode 200, and a base layer of the third meta photodiode 300 may be respectively referred to as the first base layer 120, the second base layer 220, and the third base layer 320. For example, the first meta photodiode 100 may include the first rod layer 110 and the first base layer 120, the second meta photodiode 200 may include the second rod layer 210 and the second base layer 220, and the third meta photodiode 300 may include the third rod layer 310 and the third base layer 320.

The first rod layer 110, the second rod layer 210, and the third rod layer 310 may respectively have a first width W₁, a second width W₂, and a third width W₃ different from each other in a direction (X direction or Y direction) perpendicular to the first direction (Z direction) so as to selectively absorb light of different wavelength bands. The first width W₁, the second width W₂, and the third width W₃ may have, for example, a range of about 50 nm or more to about 200 nm or less. The first width W₁, the second width W₂, and the third width W₃ may be selected so that the light having the wavelength that satisfies each wave mode resonance requirement among the light incident on the pixel PX may be guided inside the corresponding meta photodiode. For example, the first width W₁ may range from about 100 nm to about 200 nm, the second width W₂ may range from about 80 nm to about 150 nm, and the third width W₃ may range from about 50 nm to about 120 nm.

The first rod layer 110, the second rod layer 210, and the third rod layer 310 may respectively absorb red light, green light, and blue light among the incident light. Accordingly, one of the first rod layer 110, the second rod layer 210, and the third rod layer 310 having a larger width may absorb light in a longer wavelength band. For example, the first width W₁ may be greater than the second width W₂, and the second width W₂ may be greater than the third width W₃.

FIGS. 4, 5A, and 5B show that the first rod layer 110, the second rod layer 210, and the third rod layer 310 each are in a cylindrical shape, but are not limited thereto. For example, the first rod layer 110, the second rod layer 210, and the third rod layer 310 each may have a polygonal column shape such as an elliptical column, a square column, or a hexagonal column. For example, cross-sectional shapes of the first rod layer 110, the second rod layer 210, and the third rod layer 310 in the direction (X or Y direction) perpendicular to the first direction (Z direction) may be circular, elliptical, or polygonal. When the cross-sectional shapes of the first rod layer 110, the second rod layer 210, and the third rod layer 310 are circular, the first width W₁, the second width W₂, and the third width W₃ may be respectively be a first diameter, a second diameter, and a third diameter.

Referring to FIGS. 5A and 5B, a length L₁ of each of the first rod layer 110, the second rod layer 210, and the third rod layer 310 may be greater than or equal to about 500 nm, greater than or equal to about 1 μm, or greater than or equal to about 2 μm. The length L₁ of each of the first rod layer 110, the second rod layer 210, and the third rod layer 310 may have an appropriate upper limit in consideration of quantum efficiency and process difficulty that appear for each wavelength, and may be, for example, less than or equal to 4 μm, or less than or equal to 5 μm.

The shorter wavelength of light with higher energy is absorbed closer to an upper surface of a meta photodiode, and the longer wavelength of light may be absorbed at a deeper position of the meta photodiode. Accordingly, the length L₁ of each of the first rod layer 110, the second rod layer 210, and the third rod layer 310 may be determined in consideration of a position where light incident into each of the first rod layer 110, the second rod layer 210, and the third rod layer 310 is absorbed, for example, a depth position from a surface.

The first rod layer 110, the second rod layer 210, and the third rod layer 310 may have the same length L₁ as shown in FIGS. 5A and 5B. When the first rod layer 110, the second rod layer 210, and the third rod layer 310 have the same length L₁, a manufacturing process may be more easily performed. In this case, a length at which light absorption is sufficiently performed may be selected based on light of a long wavelength band. However, embodiments are not limited thereto, and the first rod layer 110, the second rod layer 210, and the third rod layer 310 may have different lengths. For example, one of the first rod layer 110, the second rod layer 210, and the third rod layer 310 having a longer length may absorb light in a longer wavelength band. For example, the length may decrease toward the first rod layer 110, the second rod layer 210, and the third rod layer 310.

At least one of the first rod layer 110, the second rod layer 210, or the third rod layer 310 may include a semiconductor material, for example, polysilicon. At least one of the first rod layer 110, the second rod layer 210, or the third rod layer 310 may include an intrinsic semiconductor material, that is, a semiconductor material that is not doped with a conductive material. The semiconductor material is not necessarily limited to silicon (Si). For example, at least one semiconductor material among the first rod layer 110, the second rod layer 210, or the third rod layer 310 may include germanium (Ge), a Group III-V compound semiconductor, or a Group II-VI compound semiconductor. At least one of the first rod layer 110, the second rod layer 210, or the third rod layer 310 may be a semiconductor material doped in a conductive type.

The first meta photodiode 100 may include the first base layer 120 having a width W₄ or a cross-sectional area greater than a cross-sectional area of the first rod layer 110, the second meta photodiode 200 may include the second base layer 220 having a width W₅ or a cross-sectional area greater than a cross-sectional area of the second rod layer 210, and the third meta photodiode 300 may include a third base layer 320 having a width W₆ or a cross-sectional area greater than a cross-sectional area of the third rod layer 310. Each of the first base layer 120, the second base layer 220, and the third base layer 320 may generate charges from mainly absorbed light or transfer the generated charges to the circuit board SU.

The width (or cross-sectional area) of each of the first base layer 120, the second base layer 220, and the third base layer 320 may be set in consideration of ease of process and/or whether charges may be easily transferred to the circuit board SU. A transistor receiving charges from each meta photodiode may be disposed on the circuit board SU, and gate electrodes G of the transistor may be respectively in contact with lower surfaces of the first base layer 120, the second base layer 220, and the third base layer 320. The widths W₄, W₅, and W₆ of the first base layer 120, the second base layer 220, and the third base layer 320 may be respectively equal to or greater than widths of the gate electrodes G electrically connected to the first base layer 120, the second base layer 220, and the third base layer 320. Each of the widths W₄, W₅, and W₆ of the first base layer 120, the second base layer 220, and the third base layer 320 may be greater than or equal to about 130 nm.

The widths W₁, W₂, and W₃ of the first rod layer 110, the second rod layer 210, and the third rod layer 310 may be relatively small in the range greater than or equal to about 50 nm and less than or equal to about 150 nm. The first rod layer 110, the second rod layer 210, and the third rod layer 310 having relatively small widths W₁, W₂, and W₃ may be more difficult to electrically connect to the gate electrodes G of the corresponding transistor. The first meta photodiode 100, the second meta photodiode 200, and the third meta photodiode 300 according to an example embodiment include the first base layer 120, the second base layer 220, and the third base layer 320 having widths W₄, W₅, and W₆ equal to or greater than the widths of the gate electrodes G of the transistor, and thus, the charges generated by the first meta photodiode 100, the second meta photodiode 200, and the third meta photodiode 300 may more stably move to the transistor.

According to another example embodiment, the widths W₄, W₅, and W₆ or the cross-sectional areas of the first base layer 120, the second base layer 220, and the third base layer 320 may be determined in consideration of the size of the pixel PX. When a width of the pixel PX of the image sensor according to an example embodiment has a size less than or equal to a diffraction limit D, the widths W₄, W₅, and W₆ of the first base layer 120, the second base layer 220, and the third base layer 320 may be ½ or less of the diffraction limit D. For example, each of the widths W₄, W₅, and W₆ of the first base layer 120, the second base layer 220, and the third base layer 320 may be about 220 nm or less. The widths W₄, W₅, and W₆ of the first base layer 120, the second base layer 220, and the third base layer 320 may be constant. According to another example embodiment, a width of the smallest base layer among the widths W₄, W₅, and W₆ of the first base layer 120, the second base layer 220, and the third base layer 320 may be greater than a width of the largest rod layer among the first rod layer 110, the second rod layer 210, and the third rod layer 310.

The lengths l1 of the first base layer 120, the second base layer 220, and the third base layer 320 may be set in consideration of the magnitude of an electric field formed in the corresponding first meta photodiode 100, second meta photodiode 200, and third meta photodiode 300. A ratio of the length l1 of each of the corresponding first base layer 120, second base layer 220, and third base layer 320 to the length L₁ of each of the first rod layer 110, the second rod layer 210, and the third rod layer 310 may be greater than or equal to about 0.5 and less than or equal to about 1.5. For example, the length l1 of each of the corresponding first base layer 120, second base layer 220, and third base layer 320 may be greater than or equal to about 500 nm, greater than or equal to about 1 μm, less than or equal to about 3 μm, or less than or equal to about 5 μm.

The first base layer 120, the second base layer 220, and the third base layer 320 may have the same length 12 as shown in FIGS. 5A and 5B. When the first base layer 120, the second base layer 220, and the third base layer 320 have the same length L₂, a manufacturing process may be more easily performed. However, the first base layer 120, the second base layer 220, and the third base layer 320 are not limited thereto. The first base layer 120, the second base layer 220, and the third base layer 320 may have different lengths.

Neighboring first base layer 120, second base layer 220, and third base layer 320 among the first base layer 120, the second base layer 220, and the third base layer 320 may be spaced apart to the extent that electrical coupling does not occur. When gaps between the first base layer 120, second base layer 220, and third base layer 320 increase, because the size of the pixel PX also increases, the gaps between the neighboring first base layer 120, second base layer 220, and third base layer 320 among the first base layer 120, the second base layer 220, and the third base layer 320 may be less than or equal to about 30 nm or less than or equal to about 20 nm.

The cross-sectional shapes of the first base layer 120, the second base layer 220, and the third base layer 320 in the direction (X direction or Y direction) perpendicular to the first direction (Z direction) may be respectively the same as or different from the cross-sectional shapes of the first rod layer 110, the second rod layer 210, and the third rod layer 310. The cross-sectional shapes of the first rod layer 110, the second rod layer 210, and the third rod layer 310 are set to more easily absorb light of a specific wavelength, while the cross-sectional shapes of the first base layer 120, the second base layer 220, and the third base layer 320 may be set to facilitate contact with the gate electrodes G of the transistor. The cross-sectional areas of the first base layer 120, the second base layer 220, and the third base layer 320 may be the maximum size in which no electrical coupling occurs in the pixel PX. For example, the cross-sectional shapes of the first base layer 120, the second base layer 220, and the third base layer 320 may have the same width. The first base layer 120, the second base layer 220, and the third base layer 320 each are shown in the shape of a square pillar, but are not limited thereto. For example, the first base layer 120, the second base layer 220, and the third base layer 320 may have a polygonal column shape such as a hexagonal column or an octagonal column.

Each of the first base layer 120, the second base layer 220, and the third base layer 320 may include a heterogeneous semiconductor material. For example, each of the first base layer 120, the second base layer 220, and the third base layer 320 may include first conductivity type semiconductor regions 121, 221, and 321 and second conductivity type semiconductor regions 122, 222, and 322, one of the first conductivity type semiconductor regions 121, 221, and 321 and the second conductivity type semiconductor regions 122, 222, and 322 may be in contact with the gate electrodes G of the transistor, and the other one of the first conductivity type semiconductor regions 121, 221, and 322 and the second conductivity type semiconductor regions 122, 222, and 322 may not be in contact with the gate electrodes G of the transistor. The first conductivity type semiconductor regions 121, 221, and 321 may each include a semiconductor material doped with a first conductivity type, and the second conductivity type semiconductor regions 122, 222, and 322 may each include a semiconductor material doped with a second conductivity type electrically opposite to the first conductivity type.

The first base layer 120, the second base layer 220, and the third base layer 320 may be formed based on a silicon semiconductor. For example, the first conductivity type semiconductor regions 121, 221, and 321 may be p-Si, and the second conductivity type semiconductor regions 122, 222, and 322 may be n-Si. The semiconductor material is not necessarily limited to silicon (Si). For example, the semiconductor material of each of the first base layer 120, the second base layer 220, and the third base layer 320 may include germanium (Ge), a Group Ill-V compound semiconductor, or a Group II-VI compound semiconductor.

The pixel array 1100 of the image sensor 1000 may further include an insulating layer 500 filled between the first meta photodiode 100, the second meta photodiode 200, and the third meta photodiode 300. The insulating layer 500 may include a dielectric material that is transparent to light in a wavelength band that the first meta photodiode 100, the second meta photodiode 200, and the third meta photodiode 300 are configured to detect. In addition, the dielectric material of the insulating layer 500 may have a refractive index lower than a refractive index of each of the first meta photodiode 100, the second meta photodiode 200, and the third meta photodiode 300. The refractive index of the dielectric material of the insulating layer 500 with respect to light having a wavelength of about 630 nm may be, for example, 1 or more or 2 or less. For example, the insulating layer 500 may include air, silicon oxide (SiO₂), silicon nitride (Si₃N₄), or aluminum oxide (Al₂O₃).

As described above, the first meta photodiode 100, the second meta photodiode 200, and the third meta photodiode 300 having a width or diameter less than a wavelength of incident light may be disposed in the pixel PX having a size smaller than or equal to a diffraction limit of an imaging optical system, such as a lens assembly. Then, each of the pixels PX may detect red light, green light, and blue light included in the incident light without a color filter. In this regard, the first meta photodiode 100, the second meta photodiode 200, and the third meta photodiode 300 disposed in one pixel PX may work together to function as a lens, a color filter, and a photodiode.

The first meta photodiode 100, the second meta photodiode 200, and the third meta photodiode 300 according to an example embodiment respectively include the first base layer 120, the second base layer 220, and the third base layer 320 each having a relatively large cross-sectional area, and thus, charges corresponding to the absorbed light may be easily transferred to the circuit board SU.

The first meta photodiode 100, the second meta photodiode 200, and the third meta photodiode 300 having a stepped shape in a direction of the length l1 according to an example embodiment are disposed at a pitch of 150 nm as shown in FIGS. 5A and 5B. The width of the first rod layer 110 may be 120 nm, the width of the second rod layer 210 may be 90 nm, the width of the third rod layer 310 may be 70 nm, and the width of each of the first base layer 120, the second base layer 220, and the third base layer 320 may be 130 nm. In addition, the length l1 of each of the first rod layer 110, the second rod layer 210, and the third rod layer 310 is designed to be 2.5 μm, and the length 12 of each of the first base layer 120, the second base layer 220, and the third base layer 320 may be 2 μm.

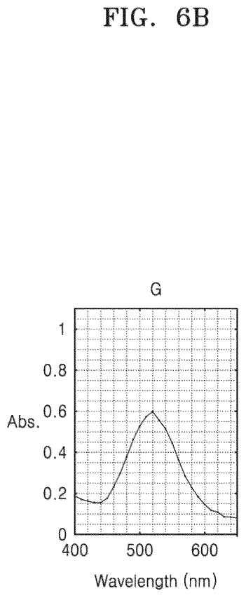

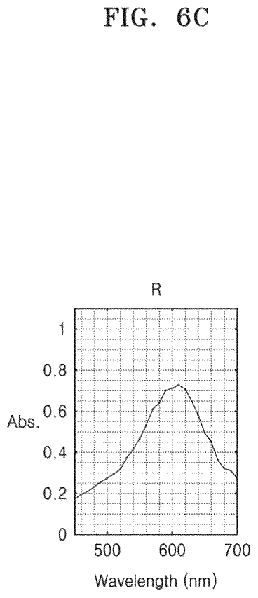

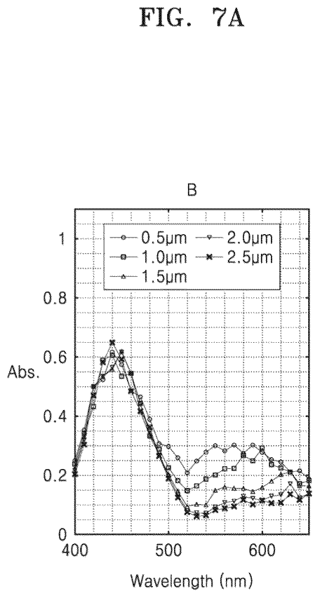

FIG. 6A is a result illustrating an absorption spectrum according to a wavelength of the first meta photodiode 100, FIG. 6B is a result illustrating an absorption spectrum according to a wavelength of the second meta photodiode 200, and FIG. 6C is a result illustrating an absorption spectrum according to a wavelength of the third meta photodiode 300 according to an example embodiment.

Referring to FIGS. 6A to 6C, the first meta photodiode 100 has an absorption rate of about 0.6 in a wavelength band of about 450 nm, the second meta photodiode 200 has an absorption rate of about 0.6 in a wavelength band of about 520 nm, and the third meta photodiode 300 has an absorption rate of about 0.7 in a wavelength band of about 620 nm. The first meta photodiode 100 selectively absorbs blue light, the second meta photodiode 200 selectively absorbs green light, and the third meta photodiode 300 selectively absorbs red light.

According to another example embodiment, light absorption rates according to lengths of the first rod layer 110, the second rod layer 210, and the third rod layer 310 are tested.

Pitches between the first meta photodiode 100, the second meta photodiode 200, and the third meta photodiode 300 may be 150 nm. The width of the first rod layer 110 may be 120 nm, the width of the second rod layer 210 may be 90 nm, the width of the third rod layer 310 may be 70 nm, and the width of each of the first base layer 120, the second base layer 220, and the third base layer 320 may be 130 nm. In addition, the length l1 of each of the first base layer 120, the second base layer 220, and the third base layer 320 may be fixed to 2 μm, and the length l1 of each of the first rod layer 110, the second rod layer 210, and the third rod layer 310 may be changed to 0.5 μm, 1 μm, 1.5 μm, 2 μm, and 2.5 μm.

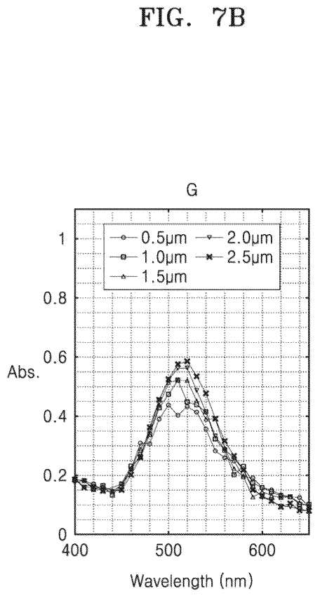

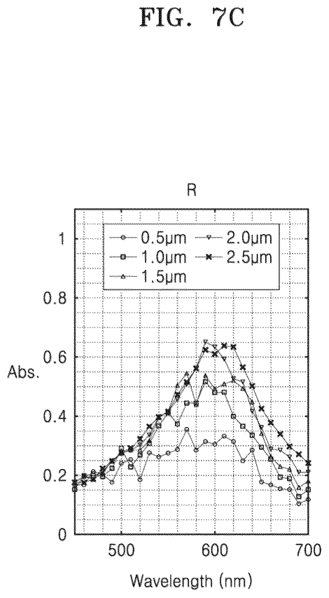

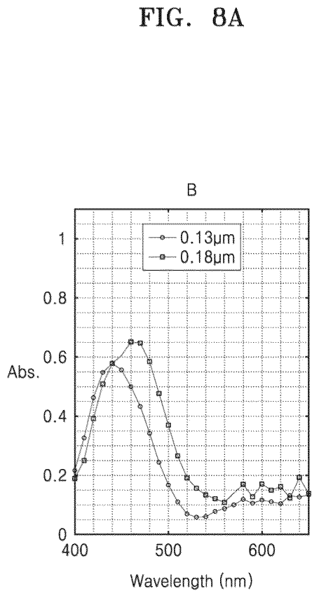

FIG. 7A is a result illustrating an absorption spectrum according to a length of the first rod layer 110 included in the first meta photodiode 100 according to an example embodiment, FIG. 7B is a result illustrating an absorption spectrum according to a length of the second rod layer 210 included in the second meta photodiode 200 according to an example embodiment, and FIG. 7C is a result illustrating an absorption spectrum according to a length of the third rod layer 310 included in the third meta photodiode 300 according to an example embodiment.

Referring to FIGS. 7A to 7C, the absorption rate of the first meta photodiode 100 is about 0.6 in a wavelength band of about 450 nm, the second meta photodiode 200 is about 0.4 to about 0.6 in a wavelength band of about 520 nm, and the absorption rate of the third meta photodiode 300 is about 0.3 to about 0.7 in a wavelength band of about 620 nm. A change in the length of each of the first rod layer 110, the second rod layer 210, and the third rod layer 310 affects the light absorption rate. For example, when the light absorption rate is 0.4 or more while lengths of the first rod layer 110, the second rod layer 210, and the third rod layer 310 are the same, the lengths of the first rod layer 110, the second rod layer 210, and the third rod layer 310 may be designed to be about 1 μm to about 2.5 μm.

According to another example embodiment, light absorption rates according to widths of the first base layer 120, the second base layer 220, and the third base layer 320 are tested.

The length l1 of each of the first rod layer 110, the second rod layer 210, and the third rod layer 310 is 2.5 μm, and the length l1 of each of the first base layer 120, the second base layer 220, and the third base layer 320 may be 2 μm. The width of the first rod layer 110 may be 120 nm, the width of the second rod layer 210 may be 90 nm, the width of the third rod layer 310 may be designed to be about 70 nm, and the widths of the first base layer 120, the second base layer 220, and the third base layer 320 may be about 130 nm and about 180 nm while gaps W_{G} between the first base layer 120, the second base layer 220, and the third base layer 320 are maintained at about 20 nm.

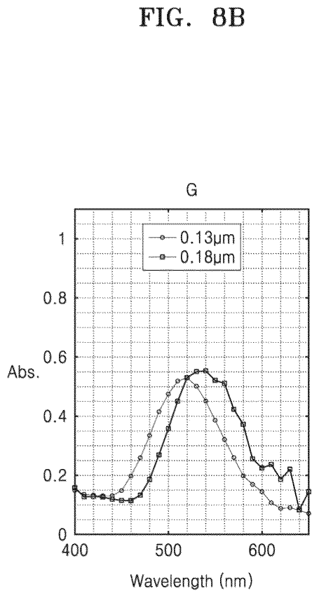

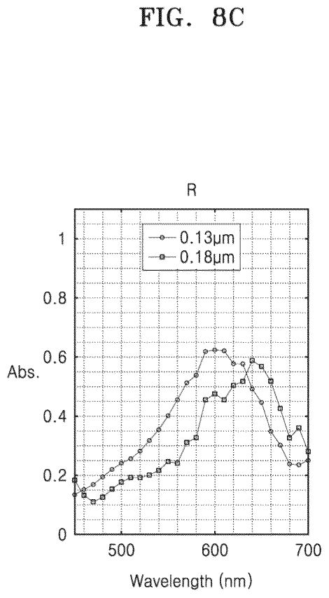

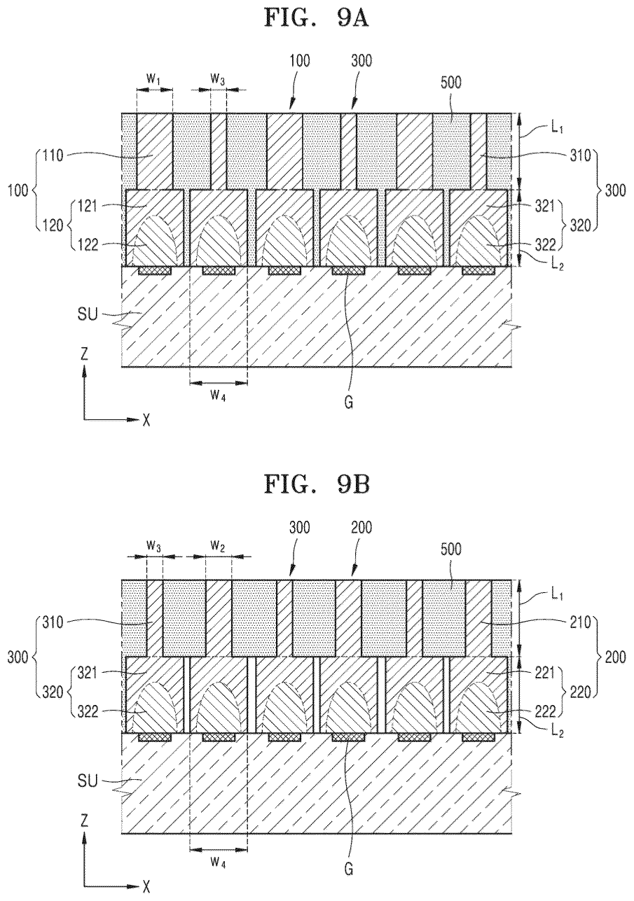

FIG. 8A is a result illustrating an absorption spectrum of a first meta photodiode according to a width of the first base layer 120 according to an example embodiment, FIG. 8B is a result illustrating an absorption spectrum of a second meta photodiode according to a width of the second base layer 220 according to an example embodiment, and FIG. 8C is a result illustrating an absorption spectrum of a third meta photodiode according to a width of the third base layer 320 according to an example embodiment.

Referring to FIGS. 8A to 8C, the light absorption rate is greater when the width of each of the first base layer 120, the second base layer 220, and the third base layer 320 is 0.18 μm than when the width of each of the first base layer 120, the second base layer 220, and the third base layer 320 is 0.13 μm in a wavelength band of about 450 nm, a wavelength band of about 520 nm, and a wavelength band of about 650 nm. A change in the width of each of the first base layer 120, the second base layer 220, and the third base layer 320 affects the light absorption rate and the wavelength band of absorbed light.

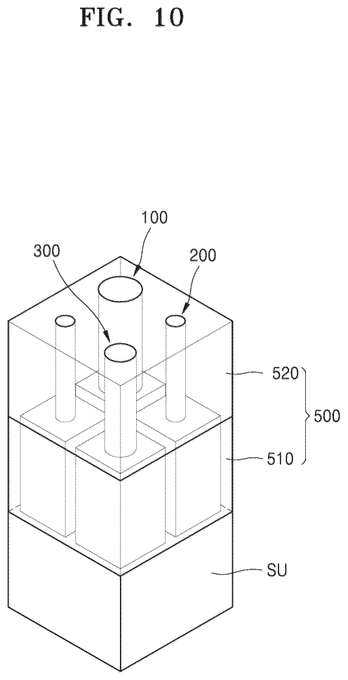

FIGS. 9A and 9B are diagrams illustrating the pixel PX according to another example embodiment. Upon comparing FIGS. 5A, 5A, 9A, and 9B, at least one of the first rod layer 110, the second rod layer 210, and the third rod layer 310 may include a material doped in a conductive type. The conductivity type of the first rod layer 110 may be the same type as the conductivity type of a region of the first base layer 120 contacting the first rod layer 110, the conductivity type of the second rod layer 210 may be the same type as the conductivity type of a region of the second base layer 220 contacting the second rod layer 210, and the conductivity type of the third rod layer 310 may be the same type as the conductivity type of a region of the third base layer 320 contacting the third rod layer 310. For example, at least one of the first rod layer 110, the second rod layer 210, and the third rod layer 310 may be a p-type semiconductor material. The conductive type is disposed in each of the first rod layer 110, the second rod layer 210, and the third rod layer 310, and thus, charges generated in the first rod layer 110, the second rod layer 210, and the third rod layer 310 may be easily moved.

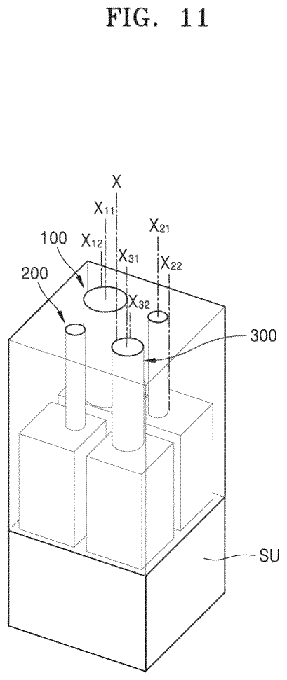

FIG. 10 is a diagram illustrating the pixel PX according to another example embodiment. Upon comparing FIG. 3 with FIG. 10, the insulating layer 500 included in the pixel PX of FIG. 10 may include a first insulating layer 510 disposed between the first rod layer 110, the second rod layer 210, and the third rod layer 310, and a second insulating layer 520 disposed between the first base layer 120, the second base layer 220, and the third base layer 320. The first insulating layer 510 and the second insulating layer 520 may include different materials. For example, the refractive index of the first insulating layer 510 may be greater than or equal to the refractive index of the second insulating layer 520. Thus, incident light may be more concentrated on the first rod layer 110, the second rod layer 210, and the third rod layer 310.

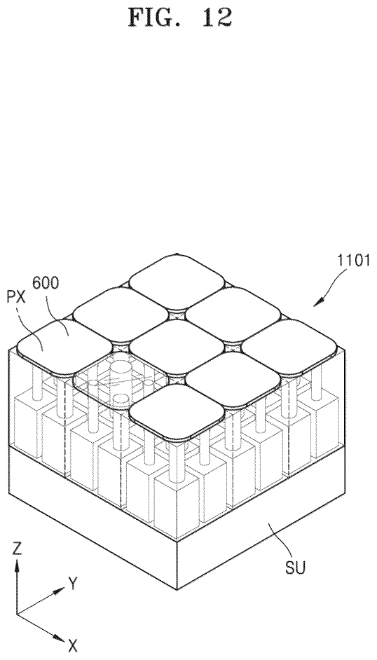

FIG. 11 is a diagram illustrating the pixel PX according to another example embodiment. In comparison with the first rod layer 110, the second rod layer 210, and the third rod layer 310 in FIG. 3, central axes of the first rod layer 110, the second rod layer 210, and the third rod layer 310 may not respectively correspond to central axes of the first base layer 120, the second base layer 220, and the third base layer 320 in FIG. 11. For example, central axes X₁₁, X₁₂, and X₁₃ of the first rod layer 110, the second rod layer 210, and the third rod layer 310 may be disposed closer to a central axis X of the pixel PX than central axes X₂₁, X₂₂, and X₂₃ of the first base layer 120, the second base layer 220, and the third base layer 320. Thus, crosstalk between the pixels PX with respect to incident light may be more effectively prevented.

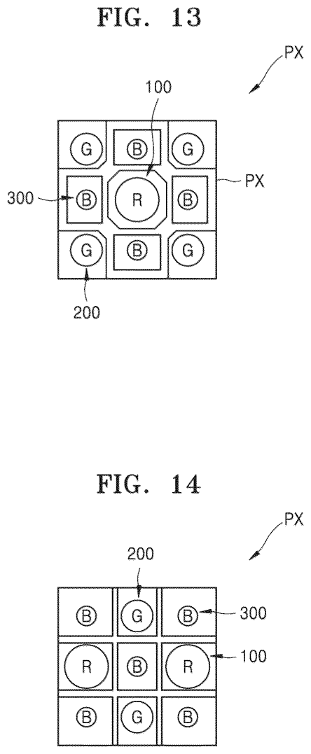

FIG. 12 is a perspective view illustrating a schematic structure of an image sensor according to another example embodiment. Referring to FIG. 12, a pixel array 1101 differs from the above-described pixel array 1100 in that the pixel array 1101 further includes a plurality of lenses 600 facing the plurality of pixels PX one-to-one. The lenses 600 may block energy exchange between the adjacent pixels PX, and thus, light efficiency may be further increased.

In the above descriptions, one pixel PX includes one first meta photodiode 100 absorbing red light, one second meta photodiode 200 absorbing green light, and two third meta photodiodes 300 absorbing blue light, but embodiments are not limited thereto, and various types and numbers of meta photodiodes may be used in image sensors of some embodiments.

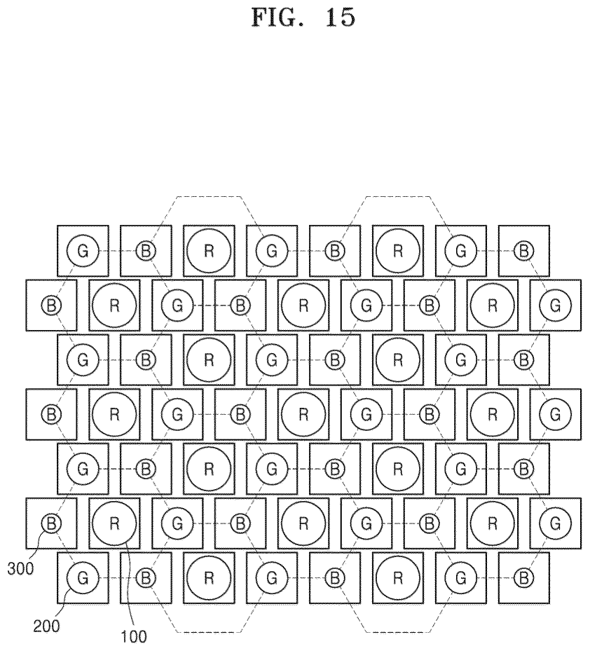

FIGS. 13 to 16 are plan views illustrating arrangement forms of various types of meta photodiodes provided in one pixel PX in each of image sensors according to example embodiments.

Referring to FIG. 13, each pixel PX in a pixel array may include one first meta photodiode 100 selectively absorbing red light, a plurality of second meta photodiodes 200 selectively absorbing green light, and a plurality of third meta photodiodes 300 selectively absorbing blue light. The first meta photodiode 100 may be disposed at the center of the pixel PX, and four second meta photodiodes 200 and four third meta photodiodes 300 may be disposed adjacent to and to surround the first meta photodiode 100 in a rectangular shape. For example, the four second meta photodiodes 200 may be disposed at vertices of a rectangle, and the four third meta photodiodes 300 may be disposed at the center of sides of the rectangle. However, embodiments are not limited thereto, and positions of the second meta photodiodes 200 and the third meta photodiodes 300 may be switched to each other.

Referring to FIG. 14, each pixel PX in the pixel array 1100 may include two first meta photodiodes 100 selectively absorbing red light, two second meta photodiodes 200 selectively absorbing green light, and five third meta photodiodes 300 selectively absorbing blue light. The two first meta photodiodes 100 may be disposed at the center of two opposite sides of the rectangle, the two second meta photodiodes 200 may be disposed at the center of the other two opposite sides of the rectangle, the one third meta photodiode 300 may be disposed at the center of the rectangle, and the four third meta photodiodes 300 may be disposed at vertices of the rectangle. A gap between two adjacent meta photodiodes among the two first meta photodiodes 100, the two second meta photodiodes 200, and the five third meta photodiodes 300 may be less than or equal to about 30 nm or less than or equal to about 20 nm.

In FIGS. 13 and 14, the sum of the numbers of the first meta photodiode 100, the second meta photodiode 200, and the third meta photodiode 300 is 9, and the nine meta photodiodes are disposed in the form of a 3×3 array. In addition, the nine meta photodiodes were disposed in the shape of a square, such as a square unit grid. However, embodiments are not limited thereto.

Referring to FIG. 15, the pixels PX may be disposed in the shape of a hexagonal grid in the pixel array 1100. One pixel PX may include one first meta photodiode 100 selectively absorbing red light, three second meta photodiodes 200 selectively absorbing green light, and three third meta photodiodes 300 selectively absorbing blue light. The first meta photodiode 100 may be disposed at the center of a hexagon, and the second meta photodiodes 200 and the third meta photodiodes 300 may be alternately disposed at the respective vertex positions of the hexagon. The two pixels PX disposed adjacent to each other to share one side may share one second meta photodiode 200 and one third meta photodiode 300 disposed at both vertices of the shared side. Therefore, one second meta photodiode 200 and one third meta photodiode 300 may be shared by three pixels PX therearound. A gap between the second meta photodiode 200 and the third meta photodiode 300 adjacent to each other may be less than or equal to about 30 nm or less than or equal to about 20 nm.

In addition, referring to FIG. 16, the pixel PX of the pixel array 1100 may include the first meta photodiode 100 selectively absorbing red light, the second meta photodiode 200 selectively absorbing green light, the third meta photodiode 300 selectively absorbing blue light, and may further include a fourth meta photodiode 400 selectively absorbing light in an infrared wavelength band. One fourth meta photodiode 400 may be disposed at the center, and four first meta photodiodes 100, four second meta photodiodes 200, and four third meta photodiodes 300 may be disposed to surround the fourth meta photodiode 400. The diameter of the fourth meta photodiode 400 may be the largest, for example, greater than 100 nm. The diameter of the fourth meta photodiode 400 may be set in the range of about 100 nm to about 200 nm.

As described above, in addition to color information of a subject, depth information of the subject may be obtained from an image sensor that further includes a meta photodiode selectively absorbing the infrared wavelength band in addition to a meta photodiode selectively absorbing R, G, and B colors. For example, a camera module including such an image sensor may further include an infrared light source that emits infrared light to the subject, and infrared information sensed by the image sensor may be used to obtain the depth information of the subject. For example, the depth information of the subject may be obtained according to the infrared information sensed by the image sensor, and the color information of the subject may be obtained by sensed visible light information. In addition, three-dimensional (3D) image information may be obtained by combining the color information and the depth information.

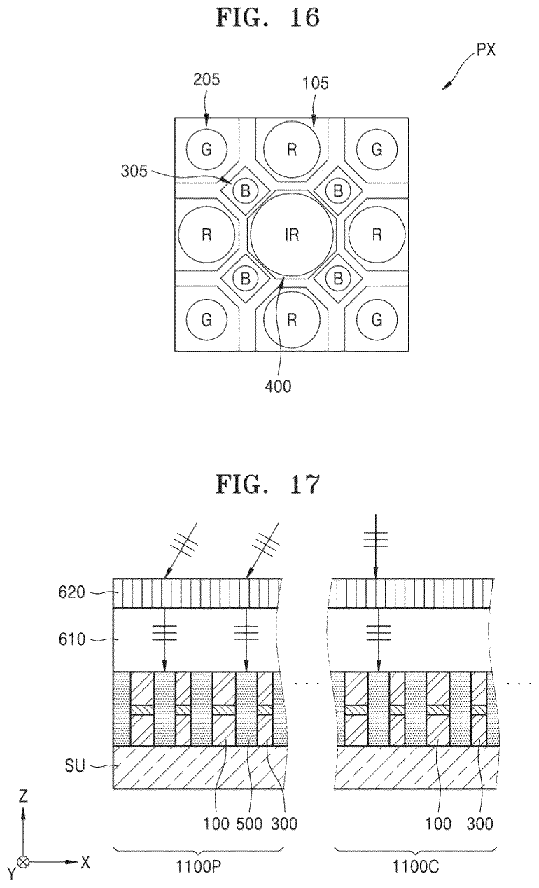

FIG. 17 is a cross-sectional view illustrating a structure of the pixel array 1100 of the image sensor 1000 according to another example embodiment. Referring to FIG. 17, the pixel array 1100 of the image sensor 1000 may further include an optical plate 620 disposed to face a light incident surface of the plurality of pixels PX. The optical plate 620 may be configured to change a traveling direction of incident light to be perpendicular to the light incident surface of the plurality of pixels PX. For example, the optical plate 620 may transmit the incident light in a center 1100C of the pixel array 1100 where the incident light is vertically incident without changing the direction of the incident light. The optical plate 620 may also vertically change the traveling direction of the incident light in a periphery 1100P of the pixel array 1100 where the incident light is obliquely incident.

The optical plate 620 may be, for example, a digital microlens array including a plurality of digital microlenses which are two-dimensionally (2D) disposed. When the optical plate 620 is a digital microlens array, the optical plate 620 may vertically change the traveling direction of the incident light while condensing the incident light on each pixel PX. To this end, the optical plate 620 may have a nano-pattern structure capable of condensing the incident light. A nano-pattern structure may include a plurality of nanostructures that change the phase of incident light differently according to an incident position of the incident light in each pixel PX. The shapes, sizes (widths and heights), gaps, arrangement forms, etc. of the plurality of nanostructures may be determined such that light immediately after passing through the optical plate 620 has a certain phase profile. For example, light immediately passing a lower surface of the optical plate 620 may have a certain phase profile. The traveling direction and focal length of the light passing through the optical plate 620 may be determined according to the phase profile.

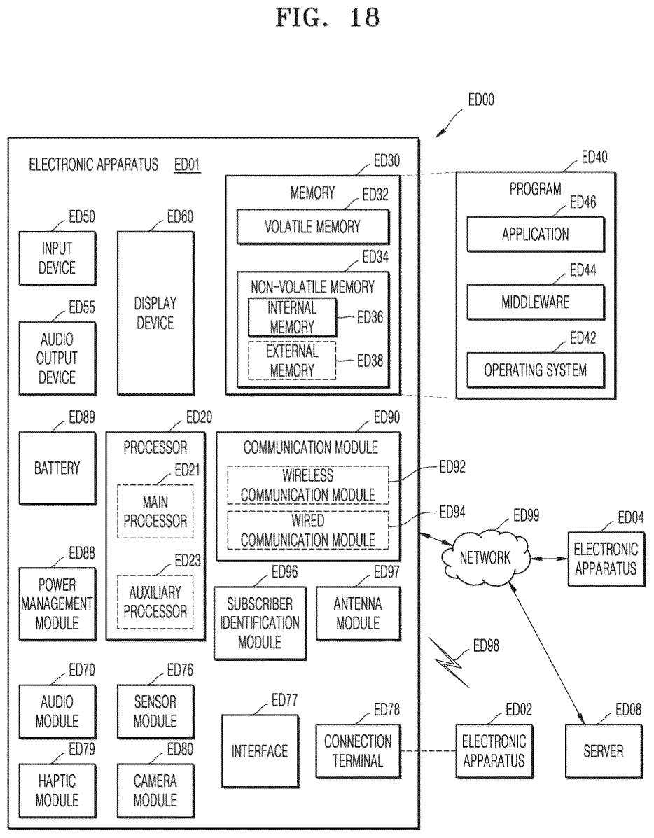

FIG. 18 is a block diagram of an electronic apparatus ED01 including the image sensor 1000. Referring to FIG. 18, in a network environment ED00, an electronic apparatus ED01 may communicate with another electronic apparatus ED02 through a first network ED98 (a short-range wireless communication network, etc.) or may communicate with another electronic apparatus ED04 and/or a server ED08 through a second network ED99 (a remote wireless communication network, etc.) The electronic apparatus ED01 may communicate with the electronic apparatus ED04 through the server ED08. The electronic apparatus ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic apparatus ED01, some of these components (e.g., the display device ED60) may be omitted or other components may be added. Some of these components may be implemented as one integrated circuit. For example, the sensor module ED76 (a fingerprint sensor, an iris sensor, an illuminance sensor, etc.) may be implemented by being embedded in the display device ED60 (a display, etc.)

The processor ED20 may control one or a plurality of other components (hardware, software components, etc.) of the electronic apparatus ED01 connected to the processor ED20 by executing software (e.g., a program ED40), and may perform various data processing or operations. As a part of data processing or computations, the processor ED20 may load commands and/or data received from other components (the sensor module ED76 and the communication module ED90, etc.) into a volatile memory ED32 and may process commands and/or data stored in the volatile memory ED32, and the resulting data may be stored in a non-volatile memory ED34. The processor ED20 may include a main processor ED21 (a central processing unit, an application processor, etc.) and an auxiliary processor ED23 (a graphics processing unit, an image signal processor, a sensor hub processor, a communication processor, etc.) that may be operated independently or together with the main processor ED21. The auxiliary processor ED23 may use less power than the main processor ED21 and may perform a specialized function.

The auxiliary processor ED23 is configured to replace the main processor ED21 while the main processor ED21 is in the inactive state (sleep state) or the main processor ED21 while the main processor ED21 is in the active state (the application execution state). Together with the processor ED21, functions and/or states related to some of the components of the electronic apparatus ED01 (the display device ED60, the sensor module ED76, the communication module ED90, etc.) may be controlled. The auxiliary processor ED23 (an image signal processor, a communication processor, etc.) may be implemented as a part of other functionally related components (the camera module ED80, the communication module ED90, etc.)

The memory ED30 may store various pieces of data required by components of the electronic apparatus ED01 (such as the processor ED20 and the sensor module ED76). The data may include, for example, input data and/or output data for software (such as the program ED40) and instructions related thereto. The memory ED30 may include the volatile memory ED32 and/or the nonvolatile memory ED34.

The program ED40 may be stored as software in the memory ED30 and may include an operating system ED42, middleware ED44, and/or an application ED46.

The input device ED50 may receive a command and/or data to be used in a component (such as, the processor ED20) of the electronic apparatus ED01 from the outside of the electronic apparatus ED01 (e.g., a user). The input device ED50 may include a microphone, a mouse, a keyboard, and/or a digital pen (such as, a stylus pen).

The audio output device ED55 may output a sound signal to the outside of the electronic apparatus ED01. The audio output device ED55 may include a speaker and/or a receiver. The speaker may be used for general purposes, such as, multimedia playback or recording playback, and the receiver may be used to receive an incoming call. The receiver may be incorporated as a part of the speaker or may be implemented as an independent separate device.

The display device ED60 may visually provide information to the outside of the electronic apparatus ED01. The display device ED60 may include a control circuit for controlling a display, a hologram device, or a projector, and a corresponding device. The display device ED60 may include touch circuitry configured to sense a touch, and/or sensor circuitry configured to measure the intensity of force generated by the touch (a pressure sensor, etc.)

The audio module ED70 may convert sound into an electric signal or, conversely, convert an electric signal into sound. The audio module ED70 may obtain sound through the input device ED50 or output sound through a speaker and/or headphones of the audio output device ED55 and/or another electronic apparatus (the electronic apparatus ED02, etc.) directly or wirelessly connected to the electronic apparatus ED01

The sensor module ED76 may detect an operating state (power, temperature, etc.) of the electronic apparatus ED01 or an external environmental state (a user state, etc.), and generate an electrical signal and/or data value corresponding to the sensed state. The sensor module ED76 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or more designated protocols that may be used by the electronic apparatus ED01 to directly or wirelessly connect with another electronic apparatus (the electronic apparatus ED02, etc.) The interface ED77 may include a High Definition Multimedia Interface (HDMI), a Universal Serial Bus (USB) interface, an SD card interface, and/or an audio interface.

A connection terminal ED78 may include a connector through which the electronic apparatus ED01 may be physically connected to another electronic apparatus (the electronic apparatus ED02, etc.) The connection terminal ED78 may include an HDMI connector, a USB connector, an SD card connector, and/or an audio connector (a headphones connector, etc.)

The haptic module ED79 may convert an electrical signal into a mechanical stimulus (vibration, movement, etc.) or an electrical stimulus that may be perceived by the user through tactile or kinesthetic sense. The haptic module ED79 may include a motor, a piezoelectric element, and/or an electrical stimulation device.

The camera module ED80 may capture still images and moving images. The camera module ED80 may include a lens assembly including one or more lenses, the image sensors 1000 to 1012 described above, image signal processors, and/or flashes. The lens assembly included in the camera module ED80 may collect light emitted from an object, an image of which is to be captured.

The power management module ED88 may manage power supplied to the electronic apparatus ED01. The power management module ED88 may be implemented as part of a Power Management Integrated Circuit (PMIC).

The battery ED89 may supply power to components of the electronic apparatus ED01. The battery ED89 may include a non-rechargeable primary cell, a rechargeable secondary cell, and/or a fuel cell.

The communication module ED90 may support the establishment of a direct (wired) communication channel and/or a wireless communication channel between the electronic apparatus ED01 and other electronic apparatuses (the electronic apparatus ED02, the electronic apparatus ED04, the server ED08, etc.) and perform communications through the established communication channel. The communication module ED90 may include one or a plurality of communication processors that operate independently from the processor ED20 (an application processor, etc.) and support direct communication and/or wireless communication. The communication module ED90 may include a wireless communication module ED92 (a cellular communication module, a short-range wireless communication module, and a Global Navigation Satellite System (GNSS) communication module, etc.) and/or a wired communication module ED94 (a Local Area Network (LAN) communication module, a power line communication module, etc.) Among these communication modules, a corresponding communication module may communicate with other electronic apparatuses through the first network ED98 (a short-range communication network, such as Bluetooth, WiFi Direct, or Infrared Data Association (IrDA)) or the second network ED99 (a telecommunication network, such as a cellular network, the Internet, or a computer network, such as a LAN, a wide area network (WAN), etc.) The various types of communication modules may be integrated into one component (a single chip, etc.) or implemented as a plurality of components (plural chips) separate from each other. The wireless communication module ED92 may identify and authenticate the electronic apparatus ED01 within a communication network, such as the first network ED98 and/or the second network ED99, by using subscriber information (such as, an International Mobile Subscriber Identifier (IMSI)) stored in a subscriber identification module ED96.

The antenna module ED97 may transmit or receive signals and/or power to and from the outside (other electronic apparatuses, etc.) An antenna may include a radiator having a conductive pattern formed on a substrate (a printed circuit board (PCB), etc.) The antenna module ED97 may include one or a plurality of antennas. When a plurality of antennas are included in the antenna module ED97, an antenna suitable for a communication method used in a communication network, such as the first network ED98 and/or the second network ED99, from among the plurality of antennas may be selected by the communication module ED90. Signals and/or power may be transmitted or received between the communication module ED90 and another electronic apparatus through the selected antenna. In addition to the antenna, other components (a radio-frequency integrated circuit (RFIC), etc.) may be included as part of the antenna module ED97.

Some of the components, between peripheral devices, may be connected to each other through communication methods (a bus, General Purpose Input and Output (GPIO), Serial Peripheral Interface (SPI), Mobile Industry Processor Interface (MIPI), etc.) and signals (commands, data, etc.) may be interchangeable.

Commands or data may be transmitted or received between the electronic apparatus ED01 and an external electronic apparatus (the electronic apparatus ED04) through the server ED08 connected to the second network ED99. The electronic apparatuses ED02 and ED04 may be the same type as or different types from the electronic apparatus ED01. All or part of the operations executed by the electronic apparatus ED01 may be executed by one or more of the electronic apparatuses ED02 and ED04 and the server ED08. For example, when the electronic apparatus ED01 needs to perform a function or service, the electronic apparatus ED01 may request one or more other electronic apparatuses to perform part or all of the function or service instead of executing the function or service itself. One or more other electronic apparatuses receiving the request may execute an additional function or service related to the request, and transmit a result of the execution to the electronic apparatus ED01. To this end, cloud computing, distributed computing, and/or client-server computing technologies may be used.

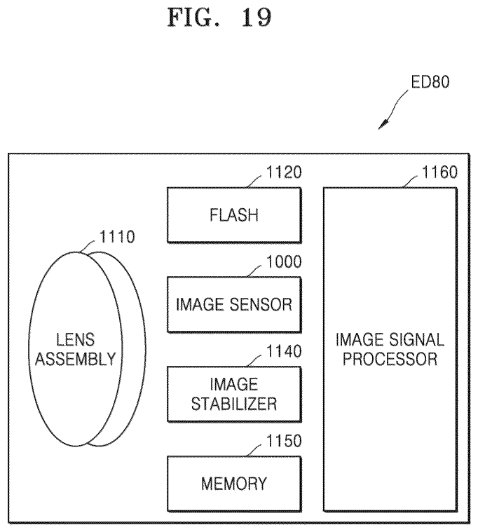

FIG. 19 is a block diagram illustrating the camera module ED80 included in the electronic apparatus ED01 of FIG. 18. Referring to FIG. 19, the camera module ED80 may include a lens assembly 1110, a flash 1120, the image sensor 1000, an image stabilizer 1140, a memory 1150 (a buffer memory, etc.), and/or an image signal processor (ISP) 1160. The lens assembly 1110 may collect light emitted from an object to be imaged. The camera module ED80 may include a plurality of lens assemblies 1170, and, in this case, the camera module ED80 may be a dual camera, a 360° camera, or a spherical camera. Some of the plurality of lens assemblies 1170 may have the same lens property (an angle of view, a focal length, an auto focus, an F-number, an optical zoom, etc.) or may have different lens properties. The lens assembly 1110 may include a wide-angle lens or a telephoto lens.

The flash 1120 may emit light to be used to enhance light emitted or reflected from an object. The flash 1120 may emit visible light or infrared light. The flash 1120 may include one or a plurality of light-emitting diodes (a Red-Green-Blue (RGB) LED, a White LED, an Infrared LED, an Ultraviolet LED, etc.), and/or a Xenon Lamp. The image sensor 1000 may be the image sensor 1000 described with reference to FIG. 1, and may obtain an image corresponding to the object by converting light emitted or reflected from the object and transmitted through the lens assembly 1110 into an electrical signal.

The image sensor 1000 may be the image sensor 1000 described with reference to FIG. 1, and types and arrangement of meta photodiodes included in the pixel PX included in the image sensor 1000 may have the forms described with reference to FIGS. 4 and 10 to 13, a combination or modified form thereof. The image sensor 1000 may have a relatively small pixel width, for example, a width equal to or smaller than a diffraction limit. The width p of each of the plurality of pixels provided in the image sensor 1000 may satisfy a condition below:

$$p < λ F$$

Here, F is the F-number of the lens assembly 1110, and λ is the center wavelength of a blue wavelength band.

The image stabilizer 1140 may move one or a plurality of lenses or the image sensor 1000 included in the lens assembly 1110 in a specific direction in response to the movement of the camera module ED80 or the electronic apparatus ED01 including the camera module ED80, or may compensate for a negative influence due to movement by controlling (adjustment of read-out timing, etc.) operating characteristics of the image sensor 1000. The image stabilizer 1140 may detect the movement of the camera module ED80 or the electronic apparatus ED01 by using a gyro sensor (not shown) or an acceleration sensor (not shown) disposed inside or outside the camera module ED80. The image stabilizer 1140 may be optically implemented.

The memory 1150 may store some or all of image data acquired by the image sensor 1000 for the next image processing operation. For example, when a plurality of images are acquired at a high speed, the acquired original data (Bayer-Patterned data, high-resolution data, etc.) is stored in the memory 1150, and only a low-resolution image is displayed, and then, may be used to transmit the original data of the selected (user selection, etc.) image to the image signal processor 1160. The memory 1150 may be integrated into the memory ED30 of the electronic apparatus ED01 or may be configured as a separate memory operated independently.

The ISP 1160 may perform image processing on images acquired by the image sensor 1000 or image data stored in the memory 1150. Image processing may include depth map generation, three dimensional (3D) modeling, panorama generation, feature point extraction, image synthesis, and/or image compensation (noise reduction, resolution adjustment, brightness adjustment, blurring, sharpening, softening, etc.) The ISP 1160 may perform control (exposure time control, readout timing control, etc.) on components (the image sensor 1000, etc.) included in the camera module ED80. The image processed by the ISP 1160 may be stored back in the memory 1150 for further processing or provided to external components of the camera module ED80 (the memory ED30, the display device ED60, the electronic apparatus ED02, the electronic apparatus ED04, the server ED08, etc.) The ISP 1160 may be integrated into the processor ED20 or configured as a separate processor operated independently from the processor ED20. When the ISP 1160 is configured as a processor separate from the processor ED20, an image processed by the ISP 1160 may be displayed on the display device ED60 after additional image processing by the processor ED20.

As illustrated in FIG. 16, when the image sensor 1000 includes a meta-photodiode that selectively absorbs infrared wavelength band and meta-photodiodes that selectively absorb red light, green light, and blue light separately, the ISP 1160 may process an infrared signal and a visible light signal acquired from the image sensor 1000 together. The ISP 1160 may obtain a depth image of an object by processing an infrared signal, obtain a color image of the object from a visible light signal, and provide a three-dimensional image of the object by combining the depth image with the color image. The ISP 1160 may also compute information on temperature or moisture of an object from the infrared signal, and provide an image of temperature distribution or moisture distribution that is combined with a two-dimensional image (color image) of the object.

The electronic apparatus ED01 may further include one or more additional camera modules each having different properties or functions. Such a camera module may also include a configuration similar to that of the camera module ED80 of FIG. 18, and an image sensor provided therein may include one or a plurality of sensors selected from image sensors having different properties, such as a Charged Coupled Device (CCD) sensor and/or a Complementary Metal Oxide Semiconductor (CMOS) sensor, an RGB sensor, a black and white (BW) sensor, an IR sensor, or a UV sensor. In this case, one of the plurality of camera modules ED80 may be a wide-angle camera and the other may be a telephoto camera. Similarly, one of the plurality of camera modules ED80 may be a front camera and the other may be a rear camera.

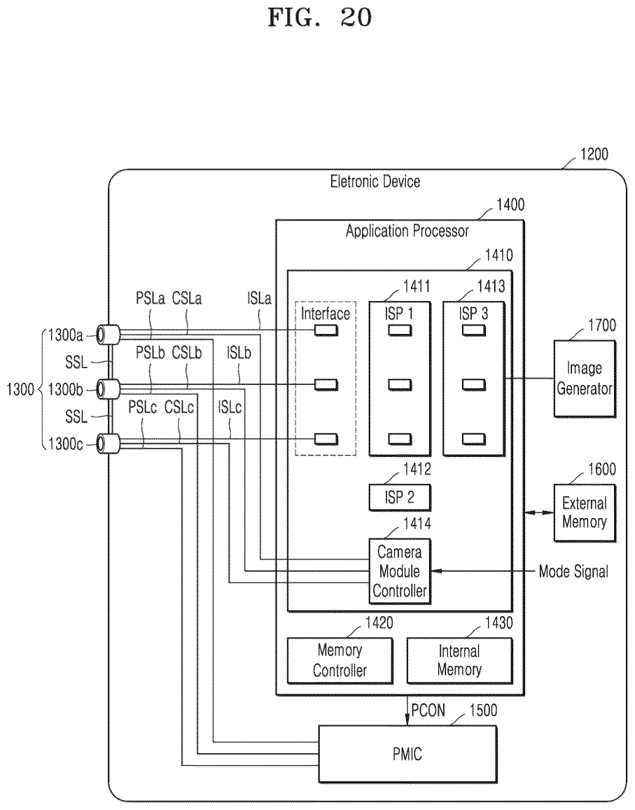

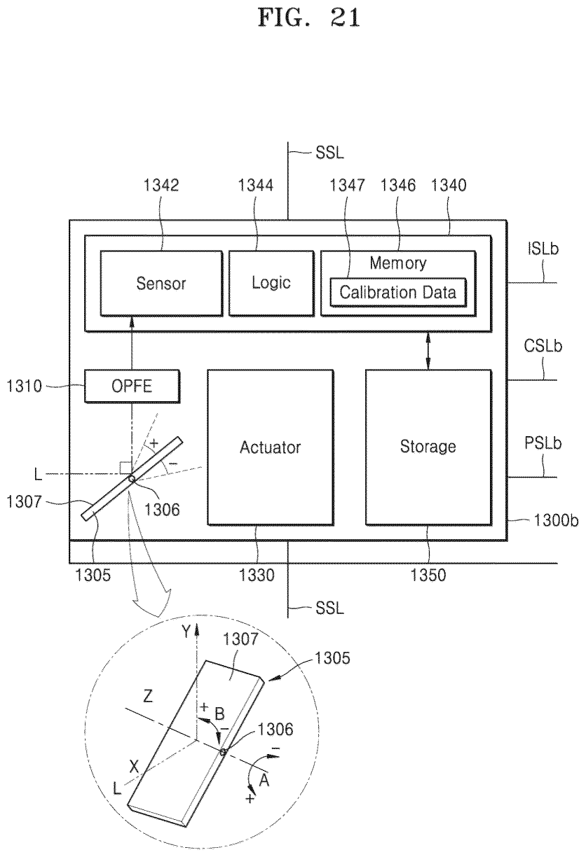

FIG. 20 is a block diagram of an electronic apparatus 1200 including a multi-camera module. FIG. 21 is a detailed block diagram of a camera module 1300b of the electronic apparatus 1200 shown in FIG. 20.

Referring to FIG. 20, the electronic apparatus 1200 may include a camera module group 1300, an application processor 1400, a PMIC 1500, an external memory 1600, and an image generator 1700.

The camera module group 1300 may include a plurality of camera modules 1300a, 1300b, and 1300c. The figures show an embodiment in which the three camera modules 1300a, 1300b, and 1300c are disposed, but the embodiments are not limited thereto. In some embodiments, the camera module group 1300 may be modified to include only two camera modules. In addition, in some embodiments, the camera module group 1300 may be modified to include n camera modules (n is a natural number of 4 or more).

Hereinafter, a detailed configuration of the camera module 1300b is described in more detail with reference to FIG. 21, but the following description may be equally applied to the other camera modules 1300a and 1300c according to an example embodiment.

Referring to FIG. 21, the camera module 1300b may include a prism 1305, an optical path folding element (hereinafter referred to as “OPFE”) 1310, an actuator 1330, an image sensing device 1340, and a storage 1350.

The prism 1305 may include a reflective surface 1307 of a light reflecting material to change a path of light L incident from the outside.

In some embodiments, the prism 1305 may change the path of light L incident in the first direction X to the second direction Y perpendicular to the first direction X. In addition, the prism 1305 may rotate the reflective surface 1307 of the light reflecting material in a direction A with respect to a central axis 1306, or rotate the central axis 1306 in a direction B to change the path of light L incident in the first direction X to the second direction Y perpendicular to the first direction X. At this time, the OPFE 1310 may also move in the third direction Z perpendicular to the first direction X and the second direction Y.

In some embodiments, as shown, the maximum rotation angle of the prism 1305 in the direction A may be 15 degrees or less in a direction plus (+) A and greater than 15 degrees in a direction minus (−) A, but embodiments are not limited thereto.

In some embodiments, the prism 1305 may move about 20 degrees, between about 10 degrees and about 20 degrees, or between about 15 degrees and about 20 degrees in a direction plus (+) B or minus (−) B, where the moving angle may be the same in the direction plus (+) B or minus (−) B, or almost similar within a range of about 1 degree.

In some embodiments, the prism 1305 may move the reflective surface 1307 of the light reflecting material in the third direction (e.g., Z) parallel to a direction of extension of the central axis 1306.

The OPFE 1310 may include, for example, an optical lens including m groups (where m is a natural number). The m lenses may change an optical zoom ratio of the camera module 1300b by moving in the second direction Y. For example, assuming that a basic optical zoom ratio of the camera module 1300b is Z, when moving the m optical lenses included in the OPFE 1310, the optical zoom ratio of the camera module 1300b may be changed greater than or equal to 3Z or 5Z or 10Z.

The actuator 1330 may move the OPFE 1310 or an optical lens to a specific position. For example, the actuator 1330 may adjust a position of the optical lens so that the image sensor 1342 is positioned at a focal length of the optical lens for accurate sensing.

The image sensing device 1340 may include an image sensor 1342, control logic 1344, and memory 1346. The image sensor 1342 may sense an image of a sensing object by using the light L provided through the optical lens. The control logic 1344 may control the overall operation of the camera module 1300b. For example, the control logic 1344 may control the operation of the camera module 1300b according to a control signal provided through a control signal line CSLb.

As an example, the image sensor 1342 may include the planar nano-optical microlens array described above. The image sensor 1342 may receive more signals separated by wavelengths for each pixel by using a nanostructure-based color separation lens array. Due to this effect, the amount of light required to generate high-quality images at high resolution and low light may be secured.

The memory 1346 may store information necessary for the operation of the camera module 1300b, such as calibration data 1347. The calibration data 1347 may include information necessary to generate image data by using the light L provided from the outside through the camera module 1300b. The calibration data 1347 may include, for example, information about a degree of rotation, information about the focal length, and information about the optical axis described above. When the camera module 1300b is implemented as a multi-state camera of which focal length changes according to the position of the optical lens, the calibration data 1347 may include a focal length value of the optical lens for each position (or state) and information related to auto focusing.

The storage 1350 may store image data sensed through the image sensor 1342. The storage 1350 may be disposed outside the image sensing device 1340 and may be implemented in the form of stacked with a sensor chip constituting the image sensing device 1340. In some embodiments, the storage 1350 may be implemented as an Electrically Erasable Programmable Read-Only Memory (EEPROM), but embodiments are not limited thereto.

Referring to FIGS. 20 and 21, in some embodiments, each of the plurality of camera modules 1300a, 1300b, and 1300c may include an actuator 1330. Accordingly, each of the plurality of camera modules 1300a, 1300b, and 1300c may include the same or different calibration data 1347 according to the operation of the actuator 1330 included therein.

In some embodiments, one camera module (e.g., 1300b) of the plurality of camera modules 1300a, 1300b, and 1300c may be a folded lens type camera module including the prism 1305 and OPFE 1310 described above, and the remaining camera modules (e.g., 1300a and 1300b) may be vertical type camera modules that do not include the prism 1305 and OPFE 1310, but embodiments are not limited thereto.

In some embodiments, one camera module (e.g., 1300c) of the plurality of camera modules 1300a, 1300b, and 1300c may be a vertical type camera module that extracts depth information by using, for example, infrared ray (IR).

In some embodiments, at least two camera modules (e.g., 1300a and 1300b) among the plurality of camera modules 1300a, 1300b, and 1300c may have different fields of view. In this case, for example, optical lenses of at least two camera modules (e.g., 1300a and 1300b) among the plurality of camera modules 1300a, 1300b, and 1300c may be different from each other, but are not limited thereto.

In addition, in some embodiments, the plurality of camera modules 1300a, 1300b, and 1300c may have different fields of view. In this case, the optical lenses respectively included in the plurality of camera modules 1300a, 1300b, and 1300c may also be different from each other, but are not limited thereto.

In some embodiments, the plurality of camera modules 1300a, 1300b, and 1300c may be disposed to be physically separated from each other. For example, the plurality of camera modules 1300a, 1300b, and 1300c may not divide and use a sensing area of one image sensor 1342 but an independent sensor 1342 may be disposed inside each of the plurality of camera modules 1300a, 1300b, and 1300c.

Referring back to FIG. 20, the application processor 1400 may include an image processing device 1410, a memory controller 1420, and an internal memory 1430. The application processor 1400 may be implemented separately from the plurality of camera modules 1300a, 1300b, and 1300c. For example, the application processor 1400 and the plurality of camera modules 1300a, 1300b, and 1300c may be implemented separately as separate semiconductor chips.

The image processing device 1410 may include first to third image signal processors (ISPs) 1411, 1412, and 1413, and a camera module controller 1414.

Image data respectively generated from the camera modules 1300a, 1300b, and 1300c may be provided to the image processing device 1410 through separate image signal lines ISLa, ISLb, and ISLc. Such image data transmission may be performed by using, for example, a Camera Serial Interface (CSI) based on Mobile Industry Processor Interface (MIPI), but embodiments are not limited thereto.

The image data transmitted to the image processing device 1410 may be stored in the external memory 1600 before being transmitted to the first and second ISPs 1411 and 1412. Image data stored in the external memory 1600 may be provided to the first ISP 1411 and/or the second ISP 1412. The first ISP 1411 may correct the received image data to generate a video. The second ISP 1412 may correct the received image data to generate a still image. For example, the first and second ISPs 1411 and 1412 may perform preprocessing operations such as color correction and gamma correction on the image data.

The first ISP 1411 may include sub processors. When the number of sub processors is equal to the number of camera modules 1300a, 1300b, and 1300c, each of the sub processors may process image data provided from one camera module. When the number of sub processors is less than the number of camera modules 1300a, 1300b, and 1300c, at least one of the sub processors may process image data provided from a plurality of camera modules by using a timing sharing process. The image data processed by the first ISP 1411 and/or the second ISP 1412 may be stored in the external memory 1600 before being transferred to the image processor 1413. The image data stored in the external memory 1600 may be transmitted to the second ISP 1412. The second ISP 1412 may perform post-processing operations such as noise correction and sharpening correction on the image data.

The image data processed by the third ISP 1413 may be provided to the image generator 1700. The image generator 1700 may generate a final image by using the image data provided from the image processor 1413 according to image generating information or a mode signal.

For example, the image generator 1700 may merge at least part of the image data generated from the camera modules 1300a, 1300b, and 1300c with different fields of view according to the image generating information or the mode signal to generate an output image. In addition, the image generator 1700 may select one of the image data generated from the camera modules 1300a, 1300b, and 1300c with different fields of view according to the image generating information or the mode signal to generate an output image.

In some embodiments, the image generating information may include a zoom signal or zoom factor. In addition, in some embodiments, the mode signal may be a signal, for example, based on a mode selected by a user.

When the image generating information is a zoom signal (zoom factor) and the camera modules 1300a, 1300b, and 1300c have different observation fields (fields of views), the image generator 1700 may perform different operations according to the type of the zoom signal. For example, when the zoom signal is a first signal, the image generator 1700 may merge the image data output from the camera module 1300a and the image data output from the camera module 1300c, and then generate an output image by using a merged image signal and the image data output from the camera module 1300b that is not used for merging. When the zoom signal is a second signal different from the first signal, the image generator 1700 may not merge the image data but may select one of the image data output from the camera modules 1300a, 1300b, and 1300c and generate an output image. However, the embodiments are not limited thereto, and the method of processing image data may be modified and implemented as necessary.

The camera module controller 1414 may respectively provide control signals to the camera modules 1300a, 1300b, and 1300c. The control signals generated from the camera module controller 1414 may be respectively provided to the corresponding camera modules 1300a, 1300b, and 1300c through separate control signal lines CSLa, CSLb, and CSLc.

In some embodiments, the control signals provided from the camera module controller 1414 to the plurality of camera modules 1300a, 1300b, and 1300c may include mode information according to the mode signal. Based on the mode information, the plurality of camera modules 1300a, 1300b, and 1300c may operate in a first operation mode and a second operation mode in relation to a sensing speed.

In the first operation mode, the plurality of camera modules 1300a, 1300b, and 1300c may generate an image signal at a first speed (e.g., generate an image signal at a first frame rate) and encode the image signal to a second speed higher than the first speed (e.g., encode an image signal of a second frame rate higher than the first frame rate), and transmit the encoded image signal to the application processor 1400. At this time, the second speed may be 30 times or less than the first speed.

The application processor 1400 may store the received image signal, that is, the encoded image signal, in the memory 1430 provided inside or the storage 1600 outside the application processor 1400, and then read and decode the encoded image signal from the memory 1430 or the storage 1600, and display image data generated based on the decoded image signal. For example, the first and second ISPs 1411 and 1412 of the image processing device 1410 may perform decoding and may also perform image processing on the decoded image signal.

In the second operation mode, the plurality of camera modules 1300a, 1300b, and 1300c may generate image signals at a third speed lower than the first speed (e.g., generate image signals at a third frame rate lower than the first frame rate) and transmit the image signals to the application processor 1400. The image signals provided to the application processor 1400 may be signals that are not encoded. The application processor 1400 may perform image processing on the received image signals or store the image signals in the memory 1430 or the storage 1600.

The PMIC 1500 may supply power, for example, a power supply voltage, to each of the plurality of camera modules 1300a, 1300b, and 1300c. For example, the PMIC 1500, under the control of the application processor 1400, may supply first power to the camera module 1300a through a power signal line PSLa, supply second power to the camera module 1300b through a power signal line PSLb, and supply third power to the camera module 1300c through a power signal line PSLc.

The PMIC 1500 may generate power corresponding to each of the plurality of camera modules 1300a, 1300b, and 1300c in response to a power control signal PCON from the application processor 1400, and may also adjust a power level. The power control signal PCON may include a power adjustment signal for each operation mode of the plurality of camera modules 1300a, 1300b, and 1300c. For example, the operation mode may include a low power mode, and in this regard, the power control signal PCON may include information about a camera module operating in the low power mode and the set power level. Levels of the power provided to the plurality of camera modules 1300a, 1300b, and 1300c may be the same as or different from each other. In addition, the level of power may dynamically change.

In the image sensor according to an example embodiment, individual meta photodiodes each having a relatively small width less than or equal to the diffraction limit may separate and detect light in a plurality of types of wavelength bands. Accordingly, the image sensor according to an example embodiment may exhibit relatively high light efficiency by not using a configuration such as a color separation element or a color filter.

Each of the meta photodiodes included in the image sensor according to an example embodiment may more easily detect light by widening a cross-sectional area of a region that transfers charges corresponding to absorbed light to the circuit board.

The image sensor according to an example embodiment may be used as, for example, a multi-color sensor, a multi-wavelength sensor, and a hyper-spectral sensor, and may be used as a 3D image sensor that provides both a color image and a depth image. In addition, the image sensor according to an example embodiment may be applied as a high-resolution camera module and used in various electronic apparatuses.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claim and their equivalents.

What is claimed is:

1. An image sensor comprising:
a pixel array comprising a plurality of pixels disposed in a two-dimensional (2D) arrangement; and
a circuit board comprising a plurality of transistors respectively corresponding to the plurality of pixels,
wherein each pixel of the plurality of pixels comprises:
a first meta photodiode configured to absorb light in a first wavelength band;
a second meta photodiode configured to absorb light in a second wavelength band different from the first wavelength band; and
a third meta photodiode configured to absorb light in a third wavelength band different from the first wavelength band and the second wavelength band, and
wherein each of the first meta photodiode, the second meta photodiode, and the third meta photodiode comprises:
a rod layer extending in a first direction and having a first width in a second direction perpendicular to the first direction; and
a base layer between the rod layer and the circuit board, the base layer having a second width, in the second direction, greater than the first width.

2. The image sensor of claim 1, wherein a size of the first width of the rod layer included in the first meta photodiode, a size of the first width of the rod layer included in the second meta photodiode, and a size of the first width of the rod layer included in the third meta photodiode are different from each other.

3. The image sensor of claim 1, wherein the second width of the base layer included in the first meta photodiode, the second width of the base layer included in the second meta photodiode, and the second width of the base layer included in the third meta photodiode are the same.

4. The image sensor of claim 1, wherein a smallest width among the second width of the base layer included in the first meta photodiode, the second width of the base layer included in the second meta photodiode, and the second width of the base layer included in the third meta photodiode is greater than a largest width among the first width of the rod layer included in the first meta photodiode, the first width of the rod layer included in the second meta photodiode, and the first width of the rod layer included in the third meta photodiode.

5. The image sensor of claim 1, wherein a cross-sectional shape of the rod layer is different from a cross-sectional shape of the base layer.

6. The image sensor of claim 1, wherein gaps between the base layer included in the first meta photodiode, the base layer included in the second meta photodiode, and the base layer included in the third meta photodiode are same as each other.

7. The image sensor of claim 1, wherein gaps between the base layer included in the first meta photodiode, the base layer included in the second meta photodiode, and the base layer included in the third meta photodiode are less than or equal to 30 nm.

8. The image sensor of claim 1, wherein gaps between the base layer included in the first meta photodiode, the base layer included in the second meta photodiode, and the base layer included in the third meta photodiode are different from each other.

9. The image sensor of claim 1, wherein the rod layer entirely overlaps the base layer in the first direction.

10. The image sensor of claim 1, wherein the rod layer comprises an intrinsic semiconductor material.

11. The image sensor of claim 1, wherein the base layer comprises a p-type semiconductor region and an n-type semiconductor region.

12. The image sensor of claim 11, wherein the rod layer comprises a p-type semiconductor material.

13. The image sensor of claim 11, wherein the rod layer is in contact with the p-type semiconductor region included in the base layer.

14. The image sensor of claim 1, wherein a ratio of a length of the rod layer to a length of the base layer is greater than or equal to 0.5 and less than or equal to 1.5.

15. The image sensor of claim 1, wherein a length of the rod layer is greater than or equal to 0.5 μm and less than or equal to 3 μm.

16. The image sensor of claim 1, wherein a length of the base layer is greater than or equal to 1 μm and less than or equal to 3 μm.

17. The image sensor of claim 1, wherein the second width of the base layer is greater than or equal to a width of a gate electrode of a transistor that is included in the circuit board and contacts the base layer.

18. The image sensor of claim 1, wherein a gap between a central axis of the rod layer and a central axis of each pixel of the plurality of pixels is less than or equal to a gap between a central axis of the base layer and the central axis of each pixel of the plurality of pixels.

19. The image sensor of claim 1, wherein a width of each pixel of the plurality of pixels satisfies:
p≤D,
where D denotes a diffraction limit and p denotes a width of each pixel in a direction defining the two-dimensional (2D) arrangement of the plurality of pixels.

20. The image sensor of claim 1, further comprising:
a first insulating layer between the rod layer included in the first meta photodiode, the rod layer included in the second meta photodiode, and the rod layer included in the third meta photodiode; and
a second insulating layer between the base layer included in the first meta photodiode, the base layer included in the second meta photodiode, and the base layer included in the third meta photodiode,
wherein a refractive index of the second insulating layer being less than a refractive index of the first insulating layer.
